(19) United States
(12) Patent Application Publication
(10) Pub. No.: US 2026/0020366 A1
(43) Pub. Date: Jan. 15, 2026

(54) IMAGE SENSOR

(71) Applicant: Samsung Electronics Co., Ltd., Suwon-si (KR)

(72) Inventors: Fujita MASATO, Suwon-si (KR); Hyuncheol KIM, Suwon-si (KR); Seyoung KIM, Suwon-si (KR); Sachoun PARK, Suwon-si (KR); Jueun PARK, Suwon-si (KR); Byeongjun YOO, Suwon-si (KR); Kyungduck LEE, Suwon-si (KR)

(73) Assignee: Samsung Electronics Co., Ltd., Suwon-si (KR)

(21) Appl. No.: 19/206,538

(22) Filed: May 13, 2025

(30) Foreign Application Priority Data
Jul. 10, 2024 (KR) 10-2024-0091324

(51) Int. Cl. H10F 39/00; H10F 39/18

(52) U.S. Cl. CPC H10F 39/807; H10F 39/182; H10F 39/8063; H10F 39/811

(57) ABSTRACT

An image sensor may include a plurality of photovoltaic devices in a substrate, a plurality of microlenses on the photovoltaic devices, and a pixel separation pattern between the photovoltaic devices and separating the substrate. The pixel separation pattern includes an internal pixel separation pattern and an external pixel separation pattern. The internal pixel separation pattern may be between photovoltaic devices of a same group of photovoltaic devices, which may correspond to a same microlens. The external pixel separation pattern may be between groups of the photovoltaic devices corresponding to different microlenses. A width of an open portion of the internal pixel separation pattern may be greater than a width of an open portion of the external pixel separation pattern.

### CROSS-REFERENCE TO RELATED APPLICATION

This application claims priority to and the benefit of Korean Patent Application No. 10-2024-0091324, filed in the Korean Intellectual Property Office on Jul. 10, 2024, the entire contents of which are incorporated herein by reference.

### BACKGROUND

### Field

The present disclosure relates to an image sensor.

### Description of the Related Art

An image sensor may be a semiconductor device that converts an optical image into electrical signal. The image sensor may be classified into a charge coupled device CCD type and a complementary metal oxide semiconductor CMOS type. The CMOS type image sensor may be abbreviated as CIS (CMOS image sensor). The CIS may include a plurality of pixels arranged in two dimensions. Each of the pixels may include a photodiode PD. The photodiode may convert incident light into an electrical signal.

A pixel separation pattern may be positioned between each pixel. The pixel separation pattern may have a grid structure and may partition each pixel on a plane.

### SUMMARY

The present disclosure relates to an image sensor with improved performance and/or efficiency.

According to an embodiment of the present disclosure, an image sensor may include a substrate; a plurality of photovoltaic devices in the substrate; a plurality of microlenses on the plurality of photovoltaic devices; and a pixel separation pattern between the plurality of photovoltaic devices, the pixel separation pattern separating the substrate. The plurality of photovoltaic devices may be arranged in groups of photovoltaic devices. The photovoltaic devices in each group of photovoltaic devices, among the groups of photovoltaic devices, may correspond to a same microlens among the plurality of microlenses. The groups of photovoltaic devices may correspond to different microlenses among the plurality of microlenses. The pixel separation pattern may include an internal pixel separation pattern and an external pixel separation pattern. The internal pixel separation pattern may be between the photovoltaic devices of a same group among the groups of photovoltaic devices. The external pixel separation pattern may be between the groups of photovoltaic devices. A width of an open portion of the internal pixel separation pattern may be greater than a width of an open portion of the external pixel separation pattern.

According to an embodiment of the present disclosure, an image sensor may include a substrate; a plurality of photovoltaic devices in the substrate; a plurality of microlenses on the plurality of photovoltaic devices; a ground pattern; and a pixel separation pattern between the plurality of photovoltaic devices, the pixel separation pattern separating the substrate. The plurality of photovoltaic devices may be arranged in groups of photovoltaic devices. The photovoltaic devices in each group of photovoltaic devices, among the groups of photovoltaic devices, may correspond to a same microlens among the plurality of microlenses. The groups of photovoltaic devices may correspond to different microlenses among the plurality of microlenses. The pixel separation pattern may include an internal pixel separation pattern and an external pixel separation pattern. The internal pixel separation pattern may be between the photovoltaic devices of a same group among the groups of photovoltaic devices. The external pixel separation pattern may be between the groups of photovoltaic devices. The internal pixel separation pattern and the external pixel separation pattern each may include an open portion, and the ground pattern may be in the open portion of the external pixel separation pattern.

According to an embodiment of the present disclosure, an image sensor may include a substrate; a plurality of photovoltaic devices in the substrate; a plurality of microlenses on the plurality of photovoltaic devices; a pixel separation pattern between the plurality of photovoltaic devices, the pixel separation pattern separating the substrate. The plurality of photovoltaic devices may be arranged in groups of photovoltaic devices. The photovoltaic devices in each group of photovoltaic devices, among the groups of photovoltaic devices, may correspond to a same microlens among the plurality of microlenses. The groups of photovoltaic devices may correspond to different microlenses among the plurality of microlenses. The pixel separation pattern may include an internal pixel separation pattern and an external pixel separation pattern. The internal pixel separation pattern may be between the photovoltaic devices of a same group among the groups of photovoltaic devices. The external pixel separation pattern may be between the groups of photovoltaic devices. Each of the internal pixel separation pattern and the external pixel separation pattern may include an open portion. The external pixel separation pattern and the internal pixel separation pattern may be connected to each other.

According to configurations of image sensor according to example embodiments, image sensors with improved performance and/or efficiency are provided.

### BRIEF DESCRIPTION OF THE DRAWINGS

FIG. 1 is a block diagram of an image sensor according to an embodiment.

FIG. 2 is a circuit diagram of one pixel included in image sensors according to embodiments of the present disclosure.

FIG. 3 is a plan view illustrating an image sensor according to an embodiment of the present disclosure.

FIG. 4 illustrates a shape of the pixel illustrated in FIG. 3 in a plan view.

FIG. 5 is a cross-sectional view taken along line A-A′ of FIG. 4.

FIG. 6 is a cross-sectional view taken along line B-B′ of FIG. 4.

FIG. 7 illustrates a more detailed planar shape of a pixel according to an embodiment.

FIG. 8 illustrates a pixel separation pattern in a pixel array region and a pad region of an image sensor according to an embodiment.

FIGS. 9 to 17 illustrate the same area as FIG. 4 with respect to image sensors according to various embodiments.

FIGS. 18 to 25 illustrate the same area as FIG. 4 with respect to image sensors according to various embodiments.

FIGS. 26 to 29 illustrate pixel separation patterns of a plurality of pixels according to various embodiments.

FIG. 30 illustrates an arrangement of pixels in a plane of an image sensor according to another embodiment.

FIG. 31 is a cross-sectional view taken along line C-C′ of FIG. 30.

FIG. 32 illustrates a pixel separation pattern according to another embodiment.

FIG. 33 illustrates the same region as FIG. 30 for another embodiment.

FIG. 34 illustrates the same region as FIG. 32 with respect to another embodiment.

FIG. 35 illustrates a pixel arrangement of an image sensor according to another embodiment.

FIG. 36 is a cross-sectional view taken along line D-D′ of FIG. 35.

FIG. 37 illustrates a pixel arrangement of an image sensor according to another embodiment.

FIG. 38 is a cross-sectional view taken along line E-E′ of FIG. 37.

### DETAILED DESCRIPTION

Hereinafter, various embodiments of the present disclosure will be described in detail with reference to the accompanying drawings so that a person of an ordinary skill in the art may implement example embodiments of the present disclosure. The present disclosure may be implemented in various different forms and is not limited to the embodiments described herein.

In order to clearly describe the present disclosure, parts irrelevant to the description are omitted, and the same reference numerals are attached to the same or similar components throughout the specification.

In addition, the size and thickness of each component shown in the drawing are arbitrarily shown for convenience of explanation, so the present disclosure is not necessarily limited to those shown. In the drawing, the thickness is enlarged to clearly express various layers and regions. And in the drawings, for convenience of explanation, the thicknesses of some layers and regions are exaggerated.

Additionally, when a part of a layer, film, region, substrate, etc. is referred to be “above” or “on” another part, this may include not only cases where it is “directly on” another part, but also cases where there are intervening elements in between. Conversely, when a part is referred to be “directly on” another part, it means that there are no intervening elements in between. In addition, being “above” or “on” a reference part means being positioned above or below the reference part, and does not necessarily mean being positioned “above” or “on” the direction opposite to gravity.

In addition, throughout the specification, when a part is referred to “include” a certain component, this means that it may further include other components rather than excluding other components, unless specifically stated to the contrary.

In addition, throughout the specification, when referring to “on a plane,” this means when the target part is viewed from above, and when referring to “in cross-section,” this means when a cross section of the target portion is cut vertically and viewed from the side.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

The notion that elements are “substantially the same” may indicate that the element may be completely the same and may also indicate that the elements may be determined to be the same in consideration of errors or deviations occurring during a process.

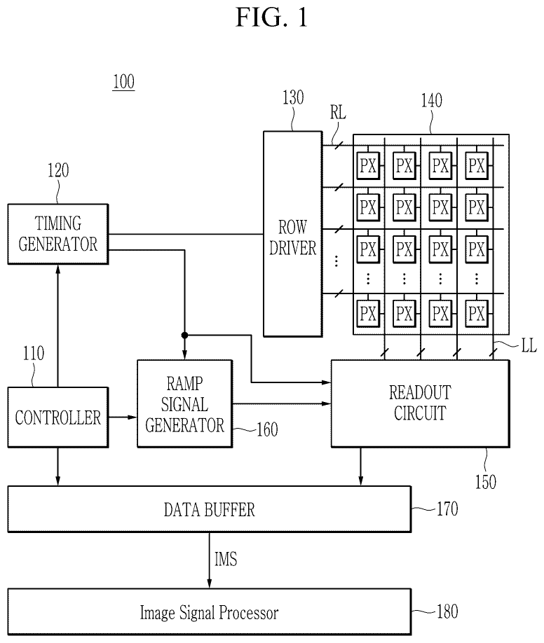

FIG. 1 is a block diagram of an image sensor according to an embodiment.

Referring to FIG. 1, the image sensor 100 according to an embodiment may include a controller 110, a timing generator 120, a row driver 130, a pixel array 140, a readout circuit 150, a ramp signal generator 160, a data buffer 170, and an image signal processor 180. In an embodiment, the image signal processor 180 may be positioned outside of the image sensor 100.

The image sensor 100 may generate an image signal by converting light received from the outside into an electrical signal. The image signal IMS may be provided to the image signal processor 180.

The image sensor 100 may be mounted on an electronic device having an image or light sensing function. For example, the image sensor 100 may be mounted in electronic devices such as cameras, smartphones, wearable devices, Internet of Things (IoT) devices, home appliances, tablet PCs (personal computers), PDAs (personal digital assistants), PMPs (portable devices), navigations, drones, and advanced drivers' assistance systems (ADAS). Also, the image sensor 100 may be mounted in an electronic device provided as a part of a vehicle, furniture, manufacturing facility, door, or various measuring devices.

The controller 110 may generally control each of components (120, 130, 150, 160, 170) included in the image sensor 100. The controller 110 may control operation timing of each of the components (120, 130, 150, 160, 170) using control signals. In an embodiment, the controller 110 may receive a mode signal indicating an image mode from an application processor and generally control the image sensor 100 based on the received mode signal. For example, the application processor may determine the image mode of the image sensor 100 according to various scenarios such as the illuminance of the imaging environment, the user's resolution setting, sensed or learned state, and provide the determined result to the controller 110 as a mode signal. The controller 110 may control a plurality of pixels of the pixel array 140 to output a pixel signal according to an imaging mode, the pixel array 140 may output a pixel signal for each of the plurality of pixels or a pixel signal for some of the plurality of pixels, and the readout circuit 150 may sample and process pixel signals received from the pixel array 140. The timing generator 120 may generate a signal that serves as a reference for the operation timing of the components of the image sensor 100. The timing generator 120 may control the timing of the row driver 130, the readout circuit 150, and the ramp signal generator 160. The timing generator 120 may provide a control signal that controls the timing of the row driver 130, the readout circuit 150, and the ramp signal generator 160.

The pixel array 140 may include a plurality of pixels PX, and a plurality of row lines RL and a plurality of column lines LL respectively connected to the plurality of pixels (PX). In an embodiment, each pixel PX may include at least one or more photovoltaic devices. The photovoltaic device may detect incident light and convert the incident light into an electrical signal according to the amount of light, that is, a plurality of analog pixel signals. The photovoltaic device may be a photodiode, a pinned diode, or the like. Additionally, the photovoltaic device may be a single-photon avalanche diode (SPAD) applied to a 3D sensor pixel. The level of the analog pixel signal output from the photovoltaic device may be proportional to the amount of charge output from the photovoltaic device. That is, the level of the analog pixel signal output from the photovoltaic device may be determined according to the amount of light received into the pixel array 140.

The plurality of row lines RL extends in a first direction and may be connected to pixels PX arranged along the first direction. For example, a control signal output from the row driver 130 to the row line RL may be transmitted to the gates of transistors of a plurality of pixels PX connected to the row line RL. The column line LL extends in a second direction crossing the first direction and may be connected to pixels PX arranged along the second direction. A plurality of pixel signals output from the plurality of pixels PX may be transmitted to the readout circuit 150 through the plurality of column lines LL.

A color filter layer and a microlens layer may be positioned on the pixel array 140. The micro lens layer may include a plurality of micro lenses, and each of the plurality of micro lenses may be positioned on top of the corresponding at least one pixel PX. The color filter layer may include color filters such as red, green, and blue, and may additionally include a white filter. For one pixel PX, a color filter of one color may be positioned between the pixel PX and the corresponding microlens.

The row driver 130 may generate a control signal for driving the pixel array 140 in response to the control signal of the timing generator 120 and provide a control signal to the plurality of pixels PX of the pixel array 140 through the plurality of row lines RL. In an embodiment, the row driver 130 may control to detect light incident on the pixel PX in units of the row line. The row line unit may include at least one row line RL. For example, as described later, the row driver 130 may provide the pixel array 140 with a transmission signal TS, a reset signal RS, and a selection signal SEL.

In response to a control signal from the timing generator 120, the readout circuit 150 may convert a pixel signal (or an electrical signal) from pixels PX connected to a row line RL selected from among a plurality of pixels PX into a pixel value representing the amount of light. The readout circuit 150 may convert a pixel signal output through a corresponding column line LL into a pixel value. For example, the readout circuit 150 may convert the pixel signal into a pixel value by comparing the ramp signal with the pixel signal. The pixel value may be image data having a plurality of bits. Specifically, the readout circuit 150 may include a selector, a plurality of comparators, a plurality of counter circuits, and the like.

The ramp signal generator 160 may generate a reference signal and transmit the reference signal to the readout circuit 150.

The ramp signal generator 160 may include a current source, a resistor, and a capacitor. The ramp signal generator 160, by adjusting the current magnitude of a variable current source or the resistance value of a variable resistor to adjust the ramp voltage, which is the voltage across the ramp resistor, may generate a plurality of ramp signals that fall or rise with a slope determined by the current magnitude of the variable current source or the resistance value of the variable resistor.

The data buffer 170 may store pixel values of a plurality of pixels PX connected to the selected column line LL transmitted from the readout circuit 150 and may output the stored pixel values in response to the enable signal from the controller 110.

The image signal processor 180 may perform an image signal processing on the image signal received from the data buffer 170. For example, the image signal processor 180 may receive a plurality of image signals from the data buffer 170 and may synthesize the received image signals to generate a single image.

In an embodiment, a plurality of pixels may be grouped in the form of M*N (where M and N are integers equal to or greater than two) to form one unit pixel group. The M*N form may be a form in which M number is arranged in the arrangement direction of the column lines LL and N number is arranged in the arrangement direction of the row lines RL. For example, one unit pixel group may include a plurality of pixels arranged in the form of 2*2, and one unit pixel group may output one analog pixel signal. The following embodiment is not limited to one pixel and may also be applied to the unit pixel group.

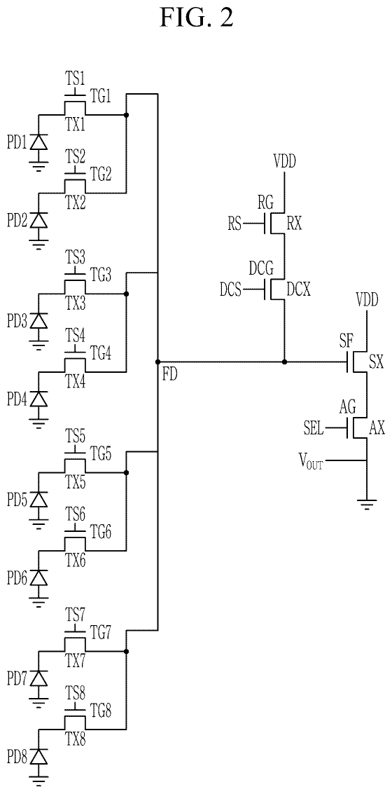

FIG. 2 is a circuit diagram of one pixel included in image sensors according to embodiments of the present disclosure.

Referring to FIG. 2, one pixel may include a plurality of photovoltaic devices (PD1, PD2, PD3, PD4, PD5, PD6, PD7, PD8). Each of the photovoltaic devices (PD1, PD2, PD3, PD4, PD5, PD6, PD7, PD8) may perform photoelectric conversion. As illustrated in FIG. 2, floating diffusion regions FD of a plurality of photovoltaic devices (PD1, PD2, PD3, PD4, PD5, PD6, PD7, PD8) may be connected into one. In FIG. 2, a configuration in which eight photovoltaic devices are connected to one floating diffusion region FD is described, but this is only an example, and the number of photovoltaic devices connected to one floating diffusion region FD may vary according to example embodiments.

Although the first photovoltaic device PD1 is mainly described below, the following description may be equally applied to other photovoltaic devices (PD2, PD3, PD4, PD5, PD6, PD7, PD8).

The first photovoltaic device PD1 may generate and accumulate electric charges according to the amount of received light. The first photovoltaic device PD1 may include an anode connected to a ground and a cathode connected to one end of the first transfer transistor TX1. The first transfer signal TS1 may be supplied to the gate TG1 of the first transfer transistor TX1, and one end of the first transfer transistor TX1 may be connected to the floating diffusion region FD. When the first transfer transistor TX1 is turned on by the first transfer signal TS1, the electric charge charged in the first photovoltaic device PD1 may be transferred to the floating diffusion region FD. The floating diffusion region FD may maintain the electric charge transferred from the photovoltaic device PD.

Each of the plurality of transfer transistors (TX1, TX2, TX3, TX4, TX5, TX6, TX7, TX8) may be connected between one of the plurality of photovoltaic devices (PD1, PD2, PD3, PD4, PD5, PD6, PD7, PD8) and a floating diffusion region FD, and may include gate electrodes (TG1, TG2, TG3, TG4, TG5, TG6, TG7, TG8) that receive a plurality of transfer signals (TS1, TS2, TS3, TS4, TS5, TS6, TS7, TS8). For example, the first transfer transistor TX1 may be connected between the first photovoltaic device PD1 and the floating diffusion region FD and may include a gate electrode TG1 that receives the first transfer signal TS1. The number of a plurality of transfer transistors (TX1, TX2, TX3, TX4, TX5, TX6, TX7, TX8) may be equal to the number of a plurality of photovoltaic devices (PD1, PD2, PD3, PD4, PD5, PD6, PD7, PD8).

A reset transistor RX may be connected between the power supply voltage VDD and the floating diffusion region FD and may include a gate electrode RG that receives the reset signal RS.

The reset transistor RX may periodically reset electric charges accumulated in the floating diffusion region FD. The drain electrode of the reset transistor RX may be connected to the source electrode of the dual conversion transistor DCX, and the source electrode may be connected to the power supply voltage VDD. When the reset transistor RX is turned on, the power supply voltage VDD connected to the source electrode of the reset transistor RX may be applied to the floating diffusion region FD. Therefore, when the reset transistor RX is turned on, the electric charges accumulated in the floating diffusion region FD may be discharged to reset the floating diffusion region FD.

The dual conversion transistor DCX may be positioned between the reset transistor RX and the floating diffusion region FD and may include a gate electrode DCG that receives the dual conversion signal DCS. The dual conversion transistor DCX may reset the floating diffusion region FD together with the reset transistor RX.

The drain electrode of the dual conversion transistor DCX may be connected to the floating diffusion region FD, and the source electrode of the dual conversion transistor DCX may be connected to the drain electrode of the reset transistor RX. When the reset transistor RX and the dual conversion transistor DCX are turned on, the power voltage VDD connected to the source electrode of the reset transistor RX may pass through the dual conversion transistor DCX and be applied to the floating diffusion region FD. Accordingly, the electric charges accumulated in the floating diffusion region FD may be discharged to reset the floating diffusion region FD.

The amplification transistor SX may output a pixel signal according to the voltage of the floating diffusion region FD. The gate SF of the amplification transistor SX may be connected to the floating diffusion region FD, the power supply voltage VDD may be supplied to the source electrode of the amplification transistor SX, and the drain electrode of the amplification transistor SX may be connected to one end of the selection transistor AX. The amplification transistor SX may constitute a source follower circuit and may output a voltage of a level corresponding to the electric charge accumulated in the floating diffusion region FD as a pixel signal.

When the selection transistor AX is turned on by the selection signal SEL, a pixel signal from the amplification transistor SX may be transmitted to the readout circuit. A selection signal SEL may be applied to the gate electrode AG of the selection transistor AX, and the drain electrode of the selection transistor AX may be connected to an output line Vout that outputs a plurality of pixel signals.

The operation of the image sensor will be described with reference to FIG. 2. First, while light is blocked, a power supply voltage VDD is applied to the drain electrode of the reset transistor RX and the drain electrode of the amplification transistor SX, and the reset transistor RX and the dual conversion transistor DCX are turned on to discharge the electric charges remaining in the floating diffusion region FD. After that, when the reset transistor RX is turned off and light from the outside is incident on the photovoltaic devices (PD1, PD2, PD3, PD4, PD5, PD6, PD7, PD8), electron-hole pairs are generated in each of the photovoltaic devices (PD1, PD2, PD3, PD4, PD5, PD6, PD7, PD8). The holes move to and accumulate in the p-type impurity region of photovoltaic devices (PD1, PD2, PD3, PD4, PD5, PD6, PD7, PD8) while the electrons move to and accumulate in the n-type impurity region. When the transfer transistors (TX1, TX2, TX3, TX4, TX5, TX6, TX7, TX8) are turned on, the electric charge such as electrons and holes are transferred to and accumulated in the floating diffusion region FD. The gate bias of the amplification transistor SX varies in proportion to the amount of accumulated electric charge, resulting in a change in the source potential of the amplification transistor SX. At this time, when the selection transistor AX is turned on, a signal due to an electric charge is read through the output line providing output voltage Vout.

The wire may be electrically connected to at least one of the gate electrodes (TG1, TG2, TG3, TG4, TG5, TG6, TG7, TG8) of the transfer transistors (TX1, TX2, TX3, TX5, TX6, TX7, TX8), the gate electrode SF of the amplification transistor SX, the gate electrode DCG of the dual conversion transistor DCX, the gate electrode RG of the reset transistor RX, and the gate electrode AG of the selection transistor AX. The wire may include a power supply voltage transmission wire for applying a power supply voltage VDD to a source electrode of the reset transistor RX or a source electrode of the amplification transistor SX. The wire may include an output line providing output volage Vout connected to the selection transistor (AX).

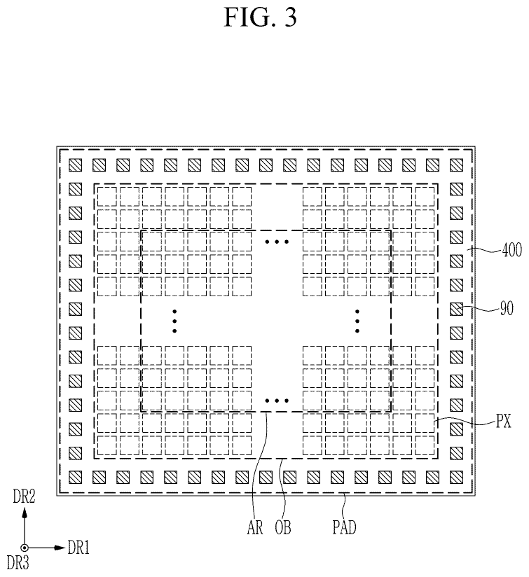

FIG. 3 is a plan view illustrating an image sensor according to an embodiment of the present disclosure.

Referring to FIG. 3, the first substrate 400 may include a pixel array region AR, an optical black region OB, and a pad region PAD in a plane. The pixel array region AR may be positioned in a central region of the first substrate 400 in a plan view. The pixel array region AR may include a plurality of pixels PX. The pixel PX may output a photoelectric signal from incident light. The pixel PX may be arranged along a row parallel to the first direction DR1 and a column parallel to the second direction DR2.

The pad region PAD may be positioned at an edge portion of the first substrate 400 and may surround the pixel array region AR. A plurality of pad terminals 90 may be positioned in the pad region PAD. The pad terminals 90 may output an electrical signal generated in the pixel PX to the outside. Alternatively, an external electrical signal or voltage may be transmitted to the pixel PX through the pad terminal 90. Since the pad region PAD is positioned at the edge portion of the first substrate 400, the pad terminal 90 may be easily connected to the outside.

The optical black region OB may be disposed between the pixel array region AR and the pad region PAD of the first substrate 400. The optical black region OB may surround the pixel array region AR. The pixel positioned in the optical black region OB may include a dummy region instead of the photoelectric conversion region 410. The signal generated in the dummy region may be used as information for removing process noise.

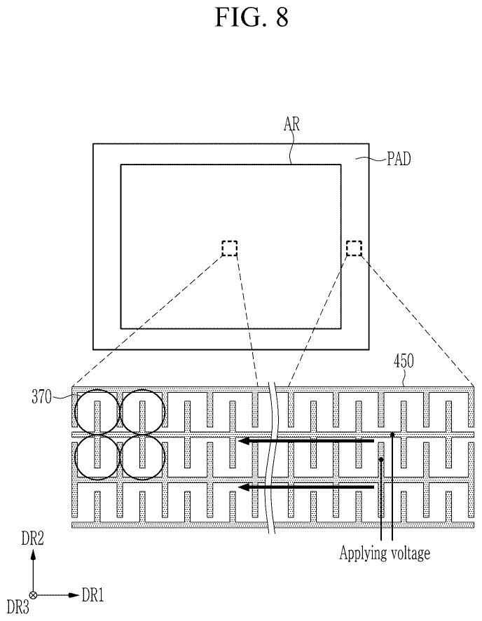

As will be described later separately with reference to FIG. 8, the pixel separation pattern positioned in the pixel array region AR may extend and connect to the optical black region OB and the pad region PAD. Therefore, a negative voltage may be applied to the pixel separation pattern in the pad region PAD, and the applied voltage may be transmitted to the pixel separation pattern positioned in the pixel array region AR. Through such negative voltage application, holes that may exist on the surface of the pixel separation pattern are fixed, thereby improving dark current characteristics. In order to apply a voltage to the pixel separation patterns, the pixel separation patterns positioned in the pixel array region AR may be connected to each other in one direction between neighboring pixels.

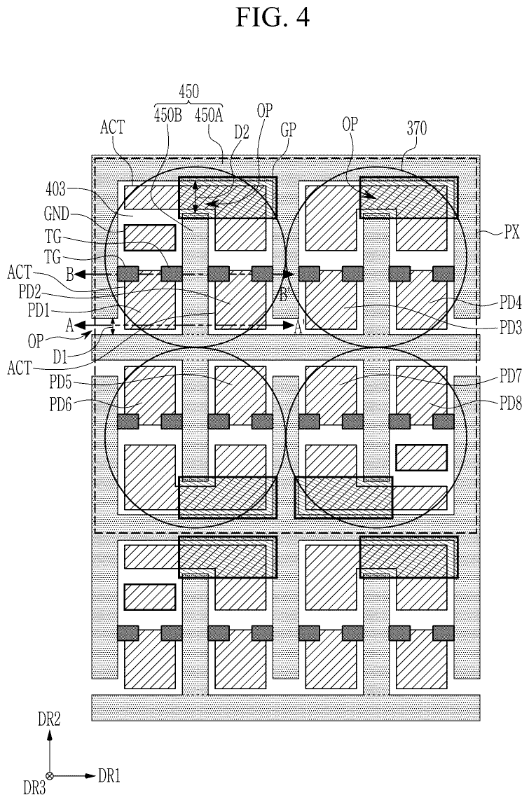

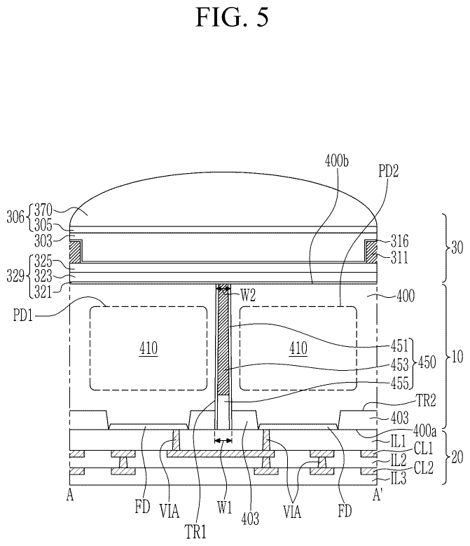

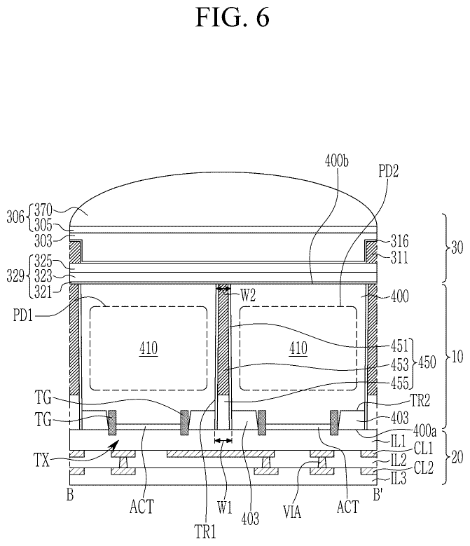

FIG. 4 illustrates a shape of the pixel PX illustrated in FIG. 3 in a plan view. FIG. 5 is a cross-sectional view taken along line A-A′ of FIG. 4. FIG. 6 is a cross-sectional view taken along line B-B′ of FIG. 4. Hereinafter, a stacked structure and an arrangement in a plan view of an image sensor according to the present embodiment will be described with reference to FIGS. 4 to 6.

Referring to FIGS. 4 to 6, the image sensor according to the present embodiment may include a first substrate 400. The first substrate 400 may include a first surface 400a and a second surface 400b facing each other. Light may be incident on the second surface 400b of the first substrate 400. The wire region 20 may be positioned on the first surface 400a of the first substrate 400, and the light transmission layer 30 may be positioned on the second surface 400b of the first substrate 400. The first substrate 400 may be a semiconductor substrate or a silicon-on-insulator SOI substrate. For example, the semiconductor substrate may include a silicon substrate, a germanium substrate, or a silicon-germanium substrate. The first substrate 400 may include a first conductivity type impurity. For example, the impurity of the first conductivity type may be a p-type impurity such as aluminum Al, boron B, indium In, and gallium Ga.

The first substrate 400 may include a pixel separation pattern 450. Referring to FIG. 4, the pixel separation pattern 450 may include an external pixel separation pattern 450A and an internal pixel separation pattern 450B. As shown in FIG. 4, the pixel PX according to an embodiment may include eight photovoltaic devices PD1, PD2, PD3, PD4, PD5, PD5, PD7, and PD8 and four microlenses 370, but example embodiments are not limited thereto. The pixel separation pattern positioned between the same microlens 370 and two corresponding photovoltaic devices may be referred to as an internal pixel separation pattern 450B, and the pixel separation pattern positioned between different microlenses 370, and corresponding photovoltaic devices and the pixel separation pattern positioned along the edge of one pixel PX may be referred to as an external pixel separation pattern 450A. The pixel separation pattern 450 may separate the first substrate 400 of the photovoltaic device.

Hereinafter, the external pixel separation pattern 450A and the internal pixel separation pattern 450B may be described separately for convenience of explanation, but the external pixel separation pattern 450A and the internal pixel separation pattern 450B are connected as one and may have the same structure.

As shown in FIG. 4, each of the internal pixel separation pattern 450B and the external pixel separation pattern 450A may include an open portion OP. The open portion OP refers to a region in which the internal pixel separation pattern 450B and the external pixel separation pattern 450A are not formed. The pixel separation pattern 450 separates the first substrate 400, and thus the first substrate 400 may be connected without separation in the open portion OP in which the pixel separation pattern 450 is not formed. As such, in the image sensor according to the present embodiment, as the internal pixel separation pattern 450B and the external pixel separation pattern 450A each include the open portion OP, even if the size of the pixel decreases, the gate electrode and the ground pattern GND in the pixel may be effectively disposed. When the size of one pixel decreases in the high-resolution image sensor, a region in a plan view for arranging a structure such as a gate electrode or a ground pattern GND may not be sufficient. However, in the image sensor according to the present embodiment, as the pixel separation pattern 450 includes the open portion OP, the first substrates 400 of neighboring photovoltaic devices are connected to each other, and a plurality of photovoltaic devices share a ground pattern GND, so that gate electrodes or ground patterns GND can be effectively arranged in a plan view. A detailed effect thereof will be described later.

FIGS. 5 and 6 illustrate a portion of a cross-section of one pixel, and two photoelectric conversion regions are illustrated in a cross-sectional view. However, this is for convenience of description, and the present disclosure is not limited thereto. That is, as illustrated in FIG. 4, one pixel may include eight photoelectric conversion regions, and the number of photoelectric conversion regions included in one pixel may vary.

Referring to FIGS. 5 and 6, the first substrate 400 may include a photoelectric conversion region 410. The photoelectric conversion region 410 may perform the same functions and roles as the photovoltaic devices (PD1, PD2, PD3, PD4, PD5, PD6, PD7, PD8) shown in FIG. 2. In FIGS. 5 and 6, the first photovoltaic device PD1 and the second photovoltaic device PD2 are illustrated.

The photoelectric conversion region 410 may be a region doped with impurity of a second conductivity type in the first substrate 400. The second conductivity type impurity may have a conductivity type opposite to the first conductivity type impurity. The second conductivity type impurity may be an n-type impurity such as phosphorus, arsenic, bismuth, and antimony. For example, each photoelectric conversion region 410 may include a first region adjacent to the first surface 400a and a second region adjacent to the second surface 400b. There may be a difference in impurity concentration between the first region and the second region of the photoelectric conversion region 410. Accordingly, the photoelectric conversion region 410 may have a potential slope between the first surface 400a and the second surface 400b of the first substrate 400. However, as another example, the photoelectric conversion region 410 may not have a potential slope between the first surface 400a and the second surface 400b of the first substrate 400.

The first substrate 400 and the photoelectric conversion region 410 may constitute a photodiode. That is, a photodiode may be configured by a p-n junction between the first substrate 400 of the first conductivity type and the photoelectric conversion region 410 of the second conductivity type. The photoelectric conversion region 410 constituting the photodiode may generate and accumulate photo charge in proportion to the intensity of incident light.

As shown in FIGS. 5 and 6, the pixel separation pattern 450 may be positioned on the first substrate 400. The pixel separation pattern 450 may have a grid structure in a plan view. As shown in FIG. 4, the pixel separation pattern 450 may partition each pixel PX in a plan view and may be positioned between a plurality of photovoltaic devices (PD1, PD2, PD3, PD4, PD5, PD6, PD7, PD8) included in a single pixel.

Referring to FIGS. 5 and 6, the pixel separation pattern 450 may be positioned in the first trench TR1. The first trench TR1 may be recessed from the first surface 400a of the first substrate 400. The pixel separation pattern 450 may extend from the first surface 400a of the first substrate 400 toward the second surface 400b. The pixel separation pattern 450 may be a deep trench isolation DTI layer. The pixel separation pattern 450 may penetrate the first substrate 400. A vertical height of the pixel separation pattern 450 may be substantially the same as a vertical thickness of the first substrate 400. For example, the width of the pixel separation pattern 450 may gradually decrease from the first surface 400a of the first substrate 400 toward the second surface 400b. The width on the first surface 400a of the pixel separation pattern 450 may be a first width W1, and the width on the second surface 400b of the pixel separation pattern 450 may be a second width W2. That is, the first width W1 may be greater than the second width W2.

The pixel separation pattern 450 may include a first separation pattern 451, a second separation pattern 453, and a capping pattern 455. The first separation pattern 451 may be positioned along a sidewall of the first trench TR1. The first separation pattern 451 may include, for example, a silicon-based insulating material (e.g., silicon nitride, silicon oxide, or silicon oxynitride) or a high-k material (e.g., hafnium oxide or aluminum oxide). As another example, the first separation pattern 451 may include a plurality of layers, and each of the layers may include a different material. The first separation pattern 451 may have a refractive index lower than that of the first substrate 400. Accordingly, a crosstalk phenomenon between the pixels PX positioned on the first substrate 400 may be prevented or reduced.

The second separation pattern 453 may be positioned in the first separation pattern 451. For example, a sidewall of the second separation pattern 453 may be surrounded by the first separation pattern 451. The first separation pattern 451 may be positioned between the second separation pattern 453 and the first substrate 400. The second separation pattern 453 may be spaced apart from the first substrate 400 by the first separation pattern 451. Accordingly, during the operation of the image sensor, the second separation pattern 453 may be electrically separated from the first substrate 400. The second separation pattern 453 may include a crystalline semiconductor material, for example, polycrystalline silicon. For example, the second separation pattern 453 may further include a dopant, and the dopant may include a first conductivity type impurity or a second conductivity type impurity.

For example, the second separation pattern 453 may further include a dopant, and the dopant may include a first conductivity type impurity or a second conductivity type impurity. Alternatively, the second separation pattern 453 may include an undoped crystalline semiconductor material. For example, the second separation pattern 453 may include a undoped polycrystalline silicon. The term “undoped” may mean that no intentional doping process has been carried out. The dopant may include an n-type dopant and a p-type dopant.

The capping pattern 455 may be positioned on the lower surface of the second separation pattern 453. The capping pattern 455 may be disposed adjacent to the first surface 400a of the first substrate 400. The capping pattern 455 may include a non-conductive material. For example, the capping pattern 455 may include a silicon-based insulating material (e.g., silicon nitride, silicon oxide, or silicon oxynitride) or a high-k material (e.g., hafnium oxide or aluminum oxide). Accordingly, the pixel separation pattern 450 may limit and/or prevent photo charges generated by incident light incident on the pixel PX from entering another adjacent pixel PX by random drift. That is, the pixel separation pattern 450 may limit and/or prevent crosstalk phenomenon between pixels PX.

The device separation pattern 403 may be positioned in the first substrate 400. For example, the device separation pattern 403 may be positioned within the second trench TR2. The second trench TR2 may be recessed from the first surface 400a of the first substrate 400. The device separation pattern 403 may be a shallow trench isolation STI layer. An upper surface of the device separation pattern 403 may be positioned in the first substrate 400. The width of the device separation pattern 403 may gradually decrease from the first surface 400a to the second surface 400b of the first substrate 400. An upper surface of the device separation pattern 403 may be vertically spaced apart from the photoelectric conversion region 410. The pixel separation pattern 450 may overlap a portion of the device separation pattern 403.

The device separation pattern 403 may include a silicon-based insulating material (e.g., silicon nitride, silicon oxide or silicon oxynitride) or a high dielectric material (e.g., hafnium oxide or aluminum oxide). The device separation pattern 403 may include the same material as the first separation pattern 451 of the pixel separation pattern 450, and in this case, the boundary between the device separation pattern 403 and the first separation pattern 451 may not be visually recognized. However, this is only an example, and the present disclosure is not limited thereto.

FIGS. 5 and 6 illustrate a configuration in which the device separation pattern 403, the pixel separation pattern 450, and the first side 400a of the first substrate 400 are positioned in the same plane, but this is only an example, and the present embodiment is not limited thereto. For example, the device separation pattern 403, the pixel separation pattern 450, and the first surface 400a of the first substrate 400 may not be coplanar. The device separation pattern 403 and the pixel separation pattern 450 may be positioned protruding or recessed from the first surface 400a of the first substrate 400.

In addition, the upper surface of the device separation pattern 403 and the upper surface of the pixel separation pattern 450 are flat, but this is an example, and the upper surface of the device separation pattern 403 and the upper surface of the pixel separation pattern 450 may include curved surfaces.

The image sensor may include an active pattern ACT and a ground pattern GND defined by the device separation pattern 403. Referring to FIG. 4, a plurality of active patterns ACT and ground patterns GND defined by a device separation pattern 403 are illustrated. The ground pattern GND is a region to which a ground voltage is applied and may be a region in which the first substrate 410 is doped with impurities of a first conductivity type.

However, the arrangement of the active pattern ACT and the ground pattern GND of FIG. 4 is an example, and the present dis closure is not limited thereto. That is, the number and arrangement form of the active pattern ACT and the ground pattern GND disposed in a plan view may vary. As shown in FIG. 4, the pixel separation pattern 450 includes an open portion OP, and thus the first substrates of a plurality of photovoltaic devices may be connected. In the case of FIG. 4, the first substrates of four photovoltaic devices are connected as one along the first direction DR1. Therefore, as shown in FIG. 4, one ground pattern (GND) may be positioned in four photoelectric conversion regions. Since the four interconnected photoelectric conversion regions share one ground pattern GND, the degree of freedom in planar design can be increased. That is, compared to the case where four photoelectric conversion regions include four ground patterns GND, more free space in a plan view may be secured. Specific effects and arrangement of pixels in a plan view will be described separately later.

Additionally, referring to FIG. 4, a gate pattern GP may be positioned on a active pattern ACT. The gate pattern GP may include polycrystalline silicon, but is not limited thereto. FIG. 4 shows a portion of the gate pattern GP, but the actual arrangement of the gate pattern GP is not limited thereto. As shown in FIG. 4, the gate pattern GP may be positioned to overlap the open portion of the pixel separation pattern 450. More specifically, it may be positioned overlapping with the open portion OP of the internal pixel separation pattern 450B. However, this is an example, and the present disclosure is not limited thereto. The gate pattern GP may be positioned without overlapping the open portion of the pixel separation pattern 450. The gate pattern GP may be positioned overlapping the active pattern ACT and may configure the reset transistor RX, dual conversion transistor DCX, amplification transistor SX, or selection transistor AX shown in FIG. 2.

Referring to FIGS. 4 to 6, the transfer transistor TX previously described in FIG. 2 may be positioned on the first surface 400a of the first substrate 400. The transfer transistor TX may be electrically connected to the photoelectric conversion region 410. The transfer transistor TX may include a transfer gate TG and a floating diffusion region FD positioned on the active pattern ACT.

Although FIGS. 4 to 6 show that there are two transfer gates TG, this is only an example, and the present disclosure is not limited thereto. That is, in FIGS. 4 to 6, the transfer transistor TX is shown as a configuration including two transfer gates TGs spaced apart from each other, which may effectively transfer electric charge formed in the photoelectric conversion region to the floating diffusion region. However, this is an example, and the transfer transistor TX may include one transfer gate TG.

The floating diffusion region FD may be adjacent to one side of the transfer gate TG. The floating diffusion region FD may be positioned in the active pattern ACT. The floating diffusion region FD may have a second conductivity type (e.g., an n-type) opposite to the first substrate 400.

The wire region 20 is positioned on the first surface 400a of the first substrate 400, and may include a plurality of insulating layers IL1, IL2, and IL3, a plurality of wire layers CL1 and CL2, and a plurality of vias VIA.

The insulating layer may include a first insulating layer IL1, a second insulating layer IL2, and a third insulating layer IL3.

The first insulating layer IL1 may cover the first surface 400a of the first substrate 400. The first insulating layer IL1 may cover the gate electrode TG. The second insulating layer IL2 may be positioned on the first insulating layer IL1. The third insulating layer IL3 may be positioned on the second insulating layer IL2.

The first to third insulating layers (IL1, IL2, IL3) may include a non-conductive material. For example, the first to third insulating layers (IL1, IL2, IL3) may include a silicon-based insulating material such as silicon oxide, silicon nitride, or silicon oxynitride.

The wire layers (CL1, CL2) may include a first wire layer CL1 and a second wire layer CL2. The first wire layer CL1 may be positioned in the second insulating layer IL2. The second wire layer CL2 may be positioned in the third insulating layer IL3.

Wires positioned in each of the first wire layer CL1 and the second wire layer CL2 may be connected to the floating diffusion region FD through a via VIA. The via VIA may penetrate the insulating layers IL1, IL2, and IL3.

Also, referring to FIGS. 4 to 6, a light transmission layer 30 positioned on the second surface 400b of the first substrate 400 may be included. The light transmission layer 30 may include an insulation structure 329, a color filter 303, and a microlens part 306. The light transmission layer 30 may condense and filter light incident from the outside, providing light to the photoelectric conversion region 410.

The color filter 303 may be positioned on the second surface 400b of the first substrate 400. The color filter 303 may be disposed in one pixel PX, respectively. In each pixel PX, the color filter 303 may include primary color filters. The color filter 303 may include a first color filter, a second color filter, and a third color filter having different colors. For example, the first color filter, the second color filter, and the third color filter may include green, red, and blue color filters, respectively. The first color filter, the second color filter, and the third color filter may be arranged in a Bayer pattern manner. As another example, the first color filter, the second color filter, and the third color filter may include a color such as cyan, magenta, or yellow.

An insulation structure 329 may be positioned between the color filter 303 and the second surface 400b of the first substrate 400. The insulation structure 329 may limit and/or prevent reflection of light so that light incident on the second surface 400b of the first substrate 400 may smoothly reach the photoelectric conversion region 410. The insulation structure 329 may be referred to as an anti-reflection structure.

The insulation structure 329 may include a first fixed charge layer 321, a second fixed charge layer 323, and a planarization layer 325 sequentially stacked on the second surface 400b of the first substrate 400. Each of the first fixed charge layer 321, the second fixed charge layer 323, and the planarization layer 325 may include a material different from each other. The first fixed charge layer 321 may include any one of aluminum oxide, tantalum oxide, titanium oxide, and hafnium oxide. The second fixed charge layer 323 may include any one of aluminum oxide, tantalum oxide, titanium oxide, and hafnium oxide. For example, the first fixed charge layer 321 may include aluminum oxide, the second fixed charge layer 323 may include hafnium oxide, and the planarization layer 325 may include silicon oxide. Although not shown, in another embodiment, a silicon anti-reflection layer (not shown) may be interposed between the second fixed charge layer 323 and the planarization layer 325. The anti-reflection layer may include silicon nitride.

The microlens part 306 may be positioned on the color filter 303. The microlens part 306 may include a flat part 305 in contact with the color filter 303 and a microlens 370 positioned on the flat part 305. The flat part 305 may include, for example, an organic material. As another example, the flat part 305 may include silicon oxide or silicon oxynitride. The microlens 370 may have a convex shape to condense light incident on the pixel PX. The shape of the lens may vary.

The light transmission layer 30 may further include a Bayer pattern 311 and a passivation layer 316. The Bayer patterns 311 may be positioned between the color filters 303 adjacent to each other to separate them from each other. The Bayer pattern 311 may be positioned on the insulation structure 329. For example, the Bayer pattern 311 may have a grid structure. The Bayer pattern 311 may include a material having a lower refractive index than the color filter 303. The Bayer pattern 311 may include an organic material. For example, the Bayer pattern 311 may be a polymer layer including silica nanoparticles. Since the Bayer pattern 311 has a low refractive index, the amount of light incident on the photoelectric conversion region 410 may be increased, and crosstalk between pixels PX may be reduced. That is, the light-receiving efficiency may be increased in each photoelectric conversion region 410, and the Signal Noise Ratio (SNR) characteristics may be improved.

The passivation layer 316 may cover the surface of the Bayer pattern 311 with a substantially uniform thickness. The passivation layer 316 may include, for example, a single layer or a multi-layer of at least one of an aluminum oxide layer and a silicon carbide oxide layer. The passivation layer 316 may protect the color filter 303 and perform a moisture absorption function.

In FIGS. 4 to 6, the center of the microlens 370 is shown in a configuration corresponding to the centers of two photoelectric conversion regions. However, this is an example, and unlike those shown in FIGS. 4 to 6, the center of the microlens 370 may not match the center of the two photoelectric conversion regions. That is, the center of the microlens 370 may be positioned to be shifted in one direction from the centers of the two photoelectric conversion regions.

The degree to which the center of the microlens 370 is shifted from the centers of the two photoelectric conversion regions may increase as it moves away from the center of the first substrate 400, that is, toward the outer portion of the first substrate 400.

Additionally, when the center of the microlens 370 is shifted from the centers of the two photoelectric conversion regions, the microlens 370 may be shifted further in one direction than the Bayer pattern 311 and the color filters 303.

This is to correct the light entering at an oblique angle in a region other than the center of the first substrate 400 so that the light entering at an oblique angle may be positioned in the center of each photoelectric conversion region.

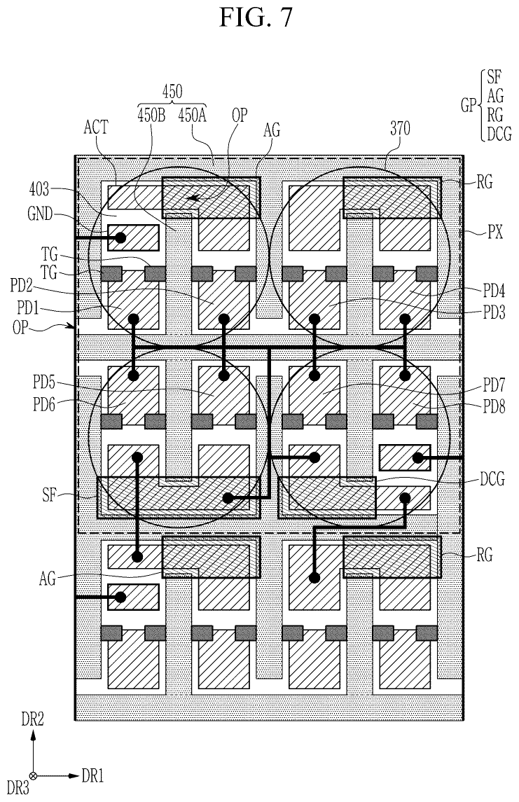

FIG. 7 illustrates a planar shape of the pixel PX according to an embodiment in more detail. FIG. 7 illustrates a connection relationship of each photovoltaic device PD1, PD2, PD3, PD4, PD5, PD6, PD7, and PD8 in the pixel PX according to an embodiment of FIG. 4, and a connection relationship of the gate pattern GP and the ground pattern GND. The same components as in FIG. 4 will not be described, and the description will focus on the connections of each photovoltaic device (PD1, PD2, PD3, PD4, PD5, PD6, PD7, PD8), gate pattern GP, and ground pattern GND. Referring to FIG. 7, the floating diffusion regions of each photovoltaic device (PD1, PD2, PD3, PD4, PD5, PD6, PD7, PD8) are connected as one. This floating diffusion region is connected to a transistor as shown in FIG. 7. In FIG. 7, the gate electrode RG of the reset transistor RX, the gate electrode DCG of the dual conversion transistor DCX, the gate electrode SF of the amplification transistor SX, and the gate electrode AG of the selection transistor AX which are shown in FIG. 2 are shown. However, this arrangement is only an example and the arrangement form of each transistor may vary. Some of the reset transistor RX, the dual conversion transistor DCX, the amplification transistor SX, and the selection transistor AX may be positioned on a separate substrate.

Referring to FIG. 7, a ground voltage may be applied to the ground pattern GND. As shown in FIG. 7, in the image sensor according to the present embodiment, an internal pixel separation pattern 450B and an external pixel separation pattern 450A include an open portion OP. Accordingly, four photovoltaic devices are connected in the first direction DR1, and the four photovoltaic devices may share one ground pattern GND. As shown in FIG. 7, when a ground voltage is applied to one ground pattern GND, the ground voltage may be applied to four photovoltaic devices parallel to each other in the first direction DR1.

Referring to FIG. 7, two ground patterns GND may be positioned in one pixel including eight photovoltaic devices. However, the arrangement of such a ground pattern GND is an example and the present disclosure is not limited thereto.

As shown in FIG. 7, one pixel PX may include four microlenses 370. One microlens 370 may be positioned corresponding to two photovoltaic devices. However, the arrangement of the microlenses 370 illustrated in FIG. 7 is an example and the present disclosure is not limited thereto.

As described above, in the image sensor according to the present embodiment, the pixel separation pattern 450 includes an open portion OP. The open portion is a region in which the pixel separation pattern 450 is not formed, and the first substrate 400 is not separated from each other in the open portion OP and is connected to each other. As described above, the pixel separation pattern 450 may include an external pixel separation pattern 450A and an internal pixel separation pattern 450B, and the open portion may be positioned in the external pixel separation pattern 450A and the internal pixel separation pattern 450B, respectively. As the pixel separation pattern 450 includes the open portion OP, a plurality of photovoltaic devices may share components of an image sensor such as a ground pattern GND, and even if the size of one pixel decreases in a high-resolution image sensor, the degree of freedom of design in a plan view may be increased.

In this case, referring to FIG. 4, the width D1 of the open portion of the external pixel separation pattern 450A may be narrower than the width D2 of the open portion of the internal pixel separation pattern 450B. The pixel separation pattern 450 may limit and/or prevent crosstalk between neighboring pixels or photovoltaic devices. In this case, crosstalk may be limited and/or minimized by forming the width D1 of the external pixel separation pattern 450A to be narrower than the width D2 of the internal pixel separation pattern 450B. That is, since the width D2 of the open portion of the internal pixel separation pattern 450B is wider than the width D1 of the open portion of the external pixel separation pattern 450A, the potential of the internal pixel separation pattern 450B is lower than the potential of the external pixel separation pattern 450A. Therefore, the photo charge formed in the photoelectric conversion region may move into a pixel that shares the same microlens instead of moving to a corresponding pixel with another microlens.

In addition, the pixel separation pattern 450 according to the present embodiment may be connected as one in the pixel array region AR and the pad region PAD. FIG. 8 illustrates a pixel separation pattern 450 in the pixel array region AR and the pad region PAD in the image sensor according to an embodiment. Referring to FIG. 8, the pixel separation pattern 450 positioned outside the pad region PAD and the pixel separation pattern 450 positioned inside the pixel array region AR may be connected in one direction (the first direction DR1 in FIG. 8). Therefore, when a voltage is applied to the pixel separation pattern 450 in the pad region PAD, a voltage may be applied to the pixel separation pattern 450 inside the pixel array region AR.

In this case, the applied voltage may be a negative voltage. Through such negative voltage application, holes that may exist on the surface of the pixel separation pattern 450 are fixed, thereby improving dark current characteristics.

That is, in the image sensor according to the present embodiment, pixel separation patterns 450 of pixels adjacent to each other in the pixel array region AR may be connected. At this time, the meaning of the connection does not mean that all the pixel separation patterns 450 positioned in the pixel array region AR are connected into one, and that there is no pixel separation pattern 450 positioned in an island shape without being connected to another pixel separation pattern 450 in the pixel array region AR.

In the embodiment of FIG. 4, a configuration is shown in which the open portions OP of the external pixel separation pattern 450A and the open portions OP of the internal pixel separation pattern 450B are formed alternately up and down in the second direction DR2, but this is an example, and the shape of the open portion of the external pixel separation pattern 450A and the internal pixel separation pattern 450B may vary.

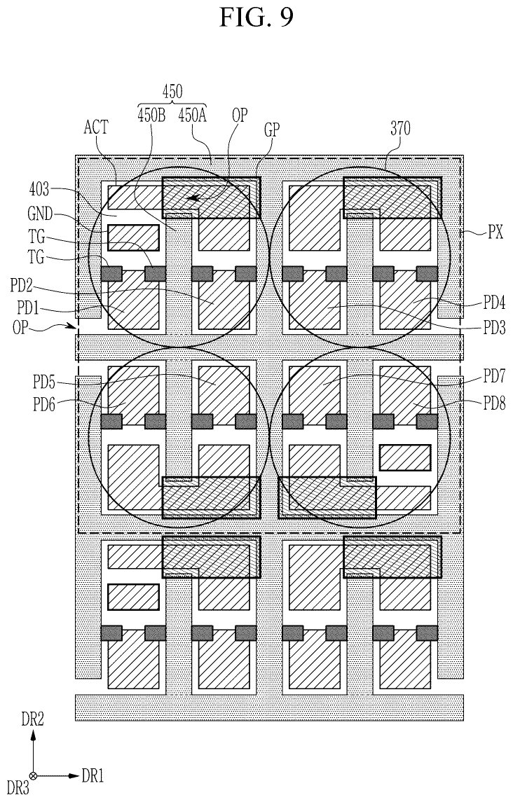

FIGS. 9 to 16 illustrate the same region as FIG. 4 for image sensors according to various embodiments. Referring to FIG. 9, the image sensor according to this embodiment is the same as the embodiment of FIG. 4 except that an open portion OP of a external pixel separation pattern 450A is formed only in a portion. A detailed description of the same elements will be omitted.

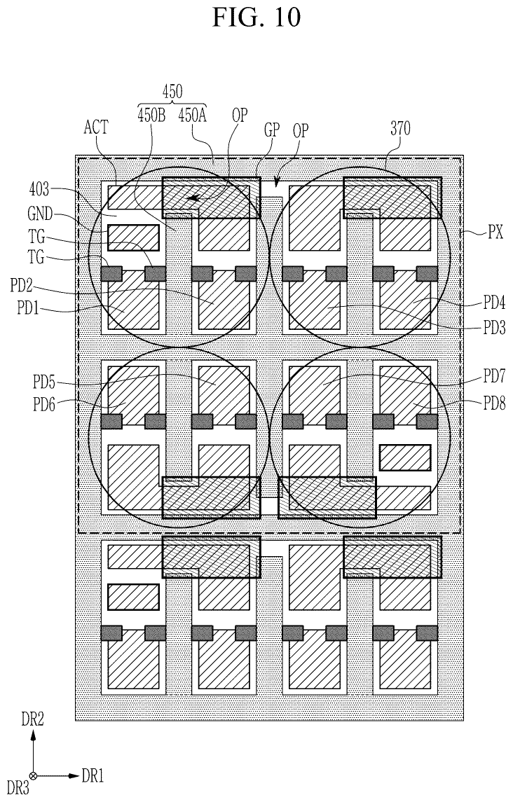

FIG. 10 illustrates the same region as FIG. 4 with respect to the image sensor according to another embodiment. Referring to FIG. 10, the image sensor according to this embodiment is the same as the embodiment of FIG. 4, except that the open portion OP of the external pixel separation pattern 450A is formed in only a portion. A detailed description of the same elements will be omitted.

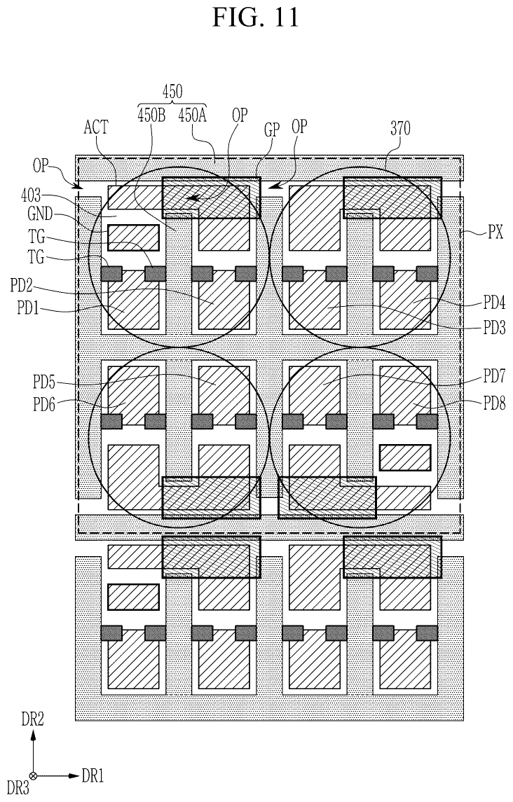

FIG. 11 shows the same region as FIG. 10 for an image sensor according to another embodiment. Referring to FIG. 11, the image sensor according to the present embodiment is the same as that of the embodiment of FIG. 10 except that an open portion OP of the external pixel separation pattern 450A and an open portion OP of the internal pixel separation pattern 450B are formed parallel to each other in the first direction DR1. A detailed description of the same elements will be omitted.

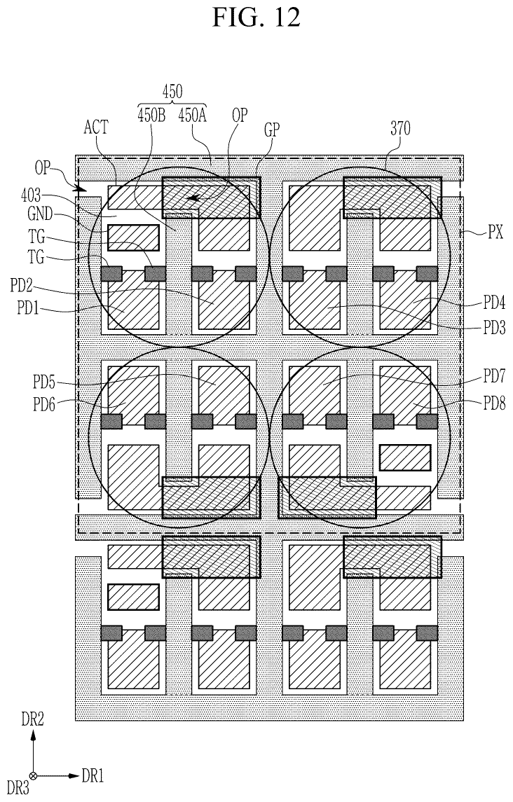

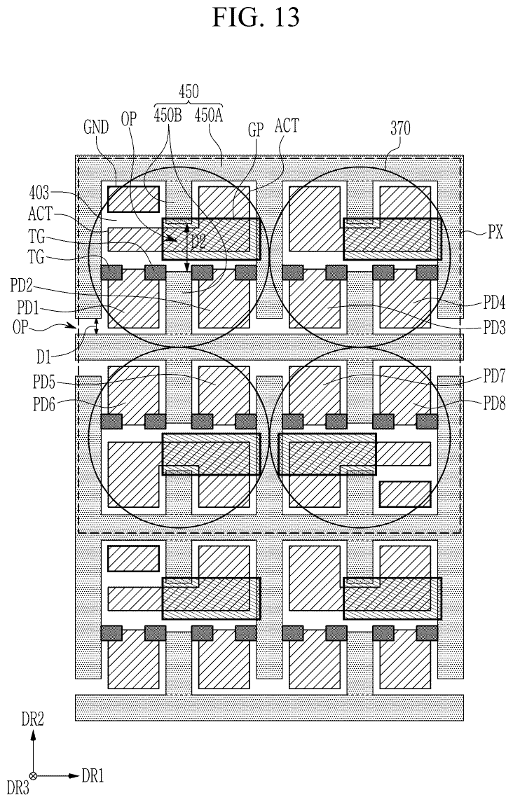

FIG. 12 shows the same region as FIG. 11 for an image sensor according to another embodiment. Referring to FIG. 12, the image sensor according to the present embodiment is the same as the embodiment of FIG. 11 except that the number of open portions OP of the external pixel separation pattern 450A is smaller than that of FIG. 11. A detailed description of the same elements will be omitted. FIG. 13 shows the same region as FIG. 4 for an image sensor according to another embodiment. Referring to FIG. 13, the image sensor according to this embodiment is the same as that of FIG. 4 except for the position of the open portion OP of the internal pixel separation pattern 450B. A detailed description of the same elements will be omitted. That is, in the embodiment of FIG. 4, the open portion OP of the internal pixel separation pattern 450B is formed in a region adjacent to the external pixel separation pattern 450A, but in the embodiment of FIG. 13, the open portion OP is formed in the central portion of the internal pixel separation pattern 450B. Referring to FIG. 13, the active pattern ACT may be positioned to overlap the open portion OP of the internal pixel separation pattern 450B. Accordingly, the position of the ground pattern GND may be different from that of FIG. 4. However, the arrangement of the ground pattern GND and the active pattern ACT is an example, and the present disclosure is not limited thereto.

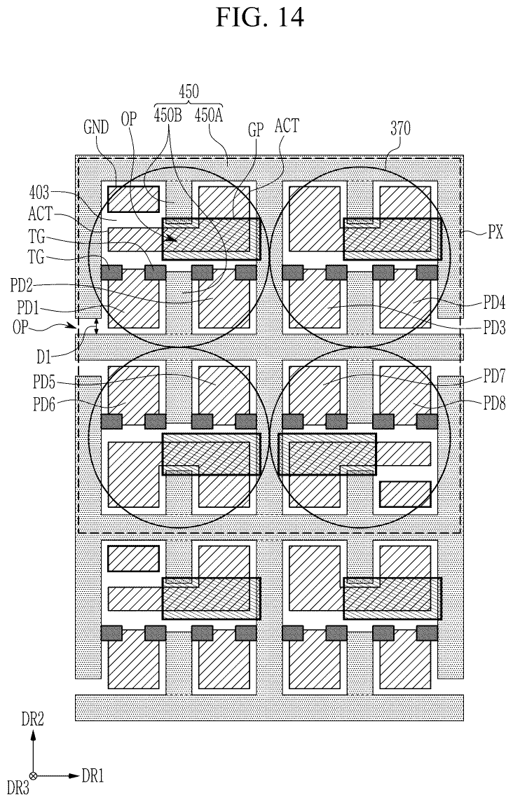

FIG. 14 shows the same region as that of FIG. 13 with respect to an image sensor according to another embodiment. Referring to FIG. 14, the image sensor according to the present embodiment is the same as the embodiment of FIG. 13 except that the open portion OP of the external pixel separation pattern 450A is formed only in a part thereof. A detailed description of the same elements will be omitted.

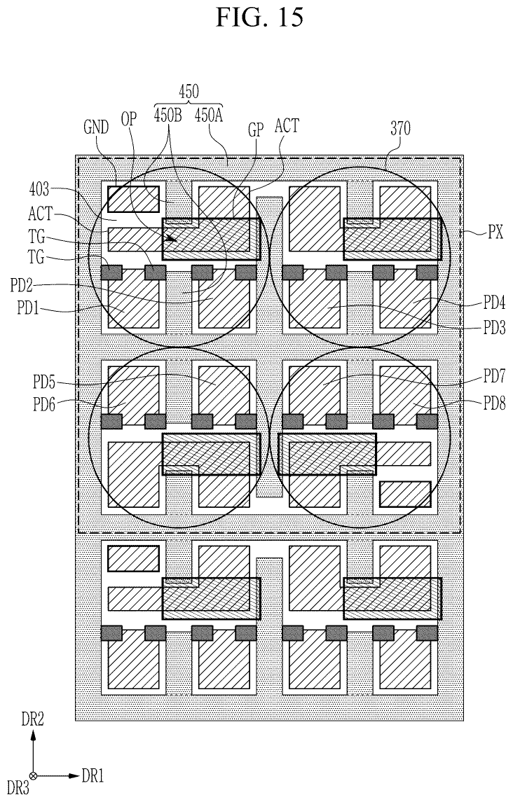

FIG. 15 shows the same region as that of FIG. 13 with respect to an image sensor according to another embodiment. Referring to FIG. 15, the image sensor according to the present embodiment is the same as the embodiment of FIG. 13 except that the open portion OP of the external pixel separation pattern 450A is formed only in a part thereof. A detailed description of the same elements will be omitted.

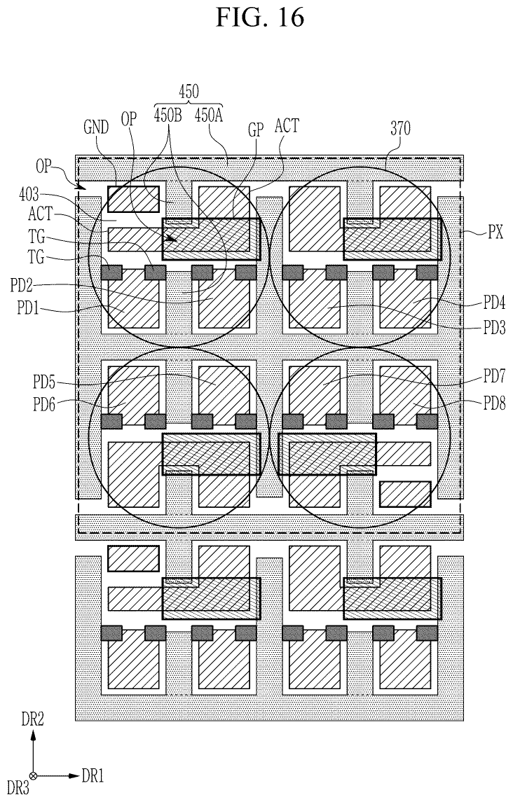

FIG. 16 shows the same region as that of FIG. 13 with respect to an image sensor according to another embodiment. Referring to FIG. 16, the image sensor according to the present embodiment is the same as the embodiment of FIG. 13 except that the open portion OP position of the external pixel separation pattern 450A is different. A detailed description of the same elements will be omitted.

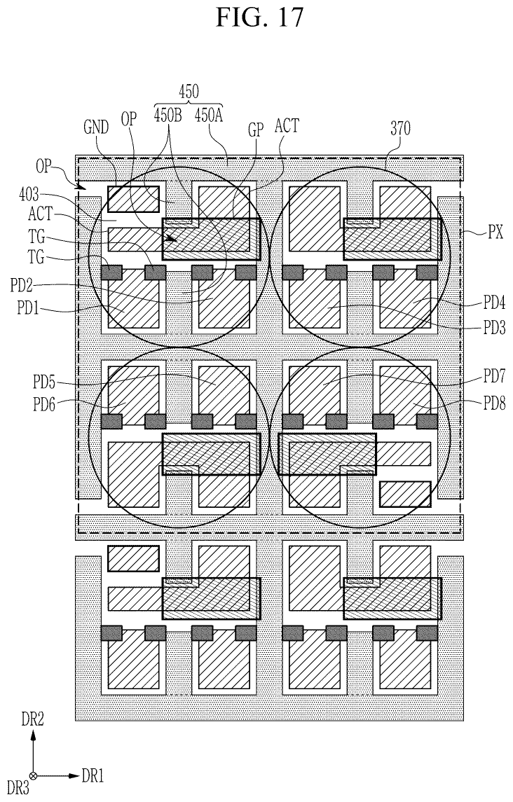

FIG. 17 shows the same region as that of FIG. 13 with respect to an image sensor according to another embodiment. Referring to FIG. 17, the image sensor according to the present embodiment is the same as the embodiment of FIG. 16 except that the number of open portions OP of the external pixel separation pattern 450A is smaller than that of FIG. 16. A detailed description of the same elements will be omitted.

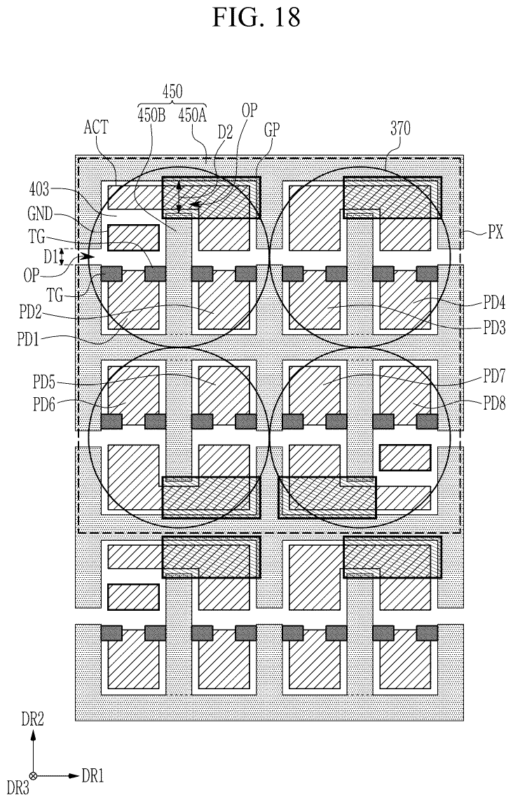

FIGS. 18 to 25 illustrate the same region as FIG. 4 for an image sensor according to various embodiments.

Referring to FIG. 18, the image sensor according to the present embodiment is the same as that of the embodiment of FIG. 4, except that the open portion OP of the external pixel separation pattern 450A is positioned near the center of one photoelectric conversion region. A detailed description of the same elements will be omitted.

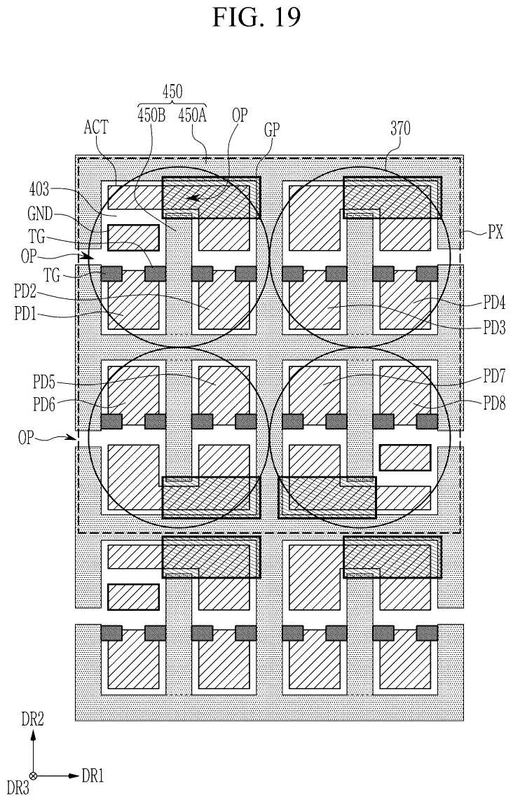

FIG. 19 shows the same region as FIG. 9 for another embodiment.

Referring to FIG. 19, the image sensor according to the present embodiment is the same as that of the embodiment of FIG. 9, except that the open portion OP of the external pixel separation pattern 450A is positioned near the center of one photoelectric conversion region. A detailed description of the same elements will be omitted.

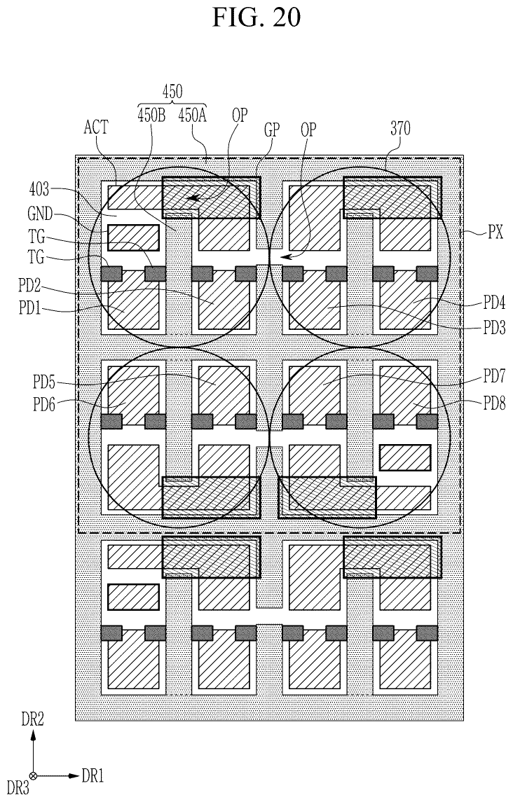

FIG. 20 shows the same region as FIG. 10 for another embodiment. Referring to FIG. 20, the image sensor according to the present embodiment is the same as that of the embodiment of FIG. 10, except that the open portion OP of the external pixel separation pattern 450A is positioned near the center of one photoelectric conversion region. A detailed description of the same elements will be omitted.

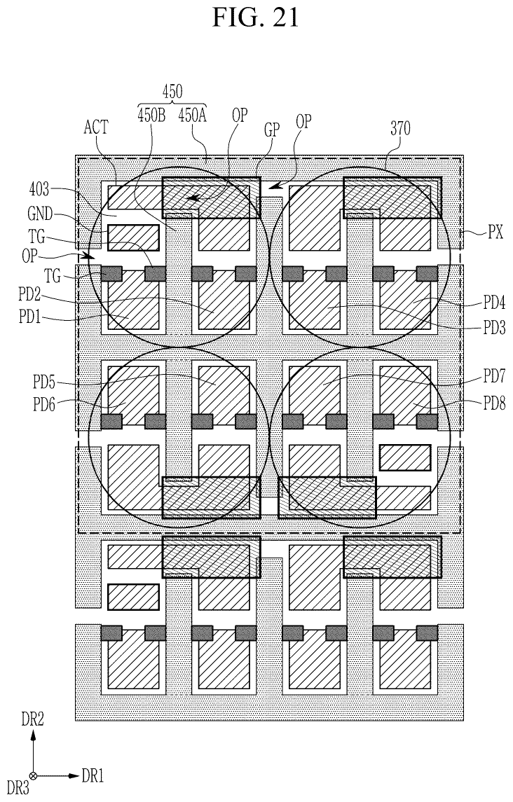

FIG. 21 shows the same region as FIG. 11 for another embodiment. Referring to FIG. 21, the image sensor according to the present embodiment is the same as that of the embodiment of FIG. 11, except that a part of the open portion OP of the external pixel separation pattern 450A is positioned near the center of one photoelectric conversion region. A detailed description of the same elements will be omitted.

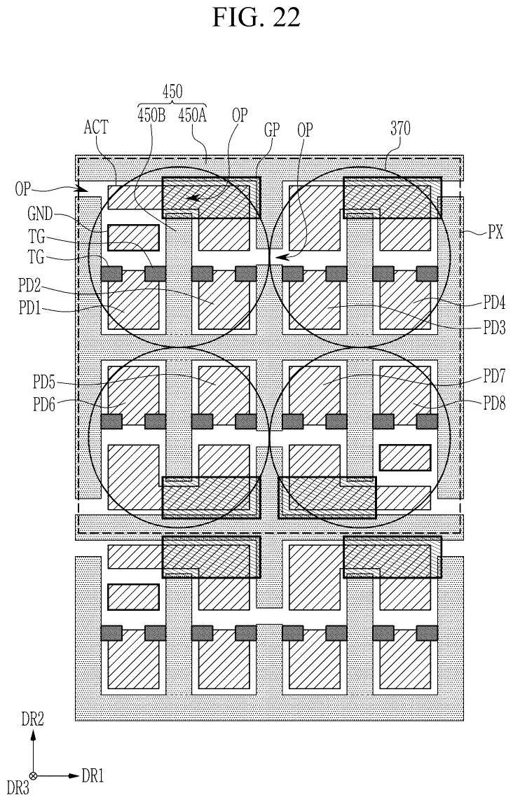

FIG. 22 shows the same region as FIG. 21 for another embodiment. Referring to FIG. 22, the image sensor according to the present embodiment is the same as the embodiment of FIG. 21 except that the positions of the open portion OP of the external pixel separation pattern 450A are different. A detailed description of the same elements will be omitted.

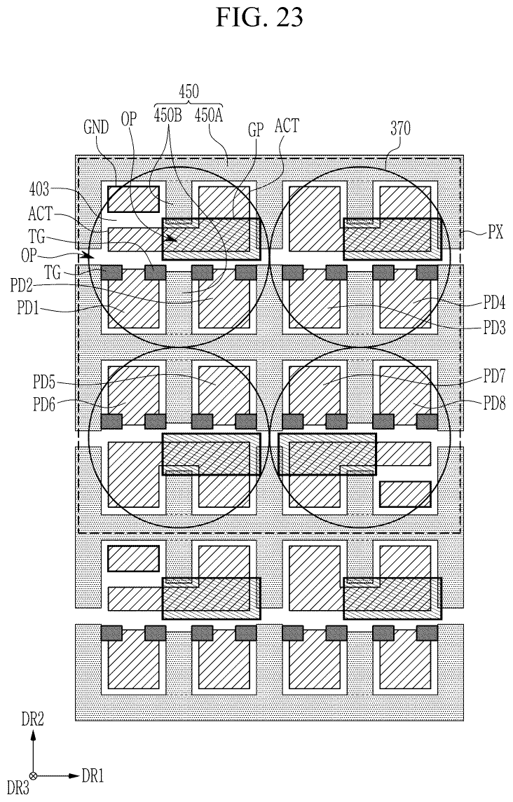

FIG. 23 shows a region like that of FIG. 21 with respect to another embodiment. Referring to FIG. 23, the image sensor according to the present embodiment is the same as the embodiment of FIG. 21 except that the positions of the open portion OP of the external pixel separation pattern 450A are different. A detailed description of the same elements will be omitted.

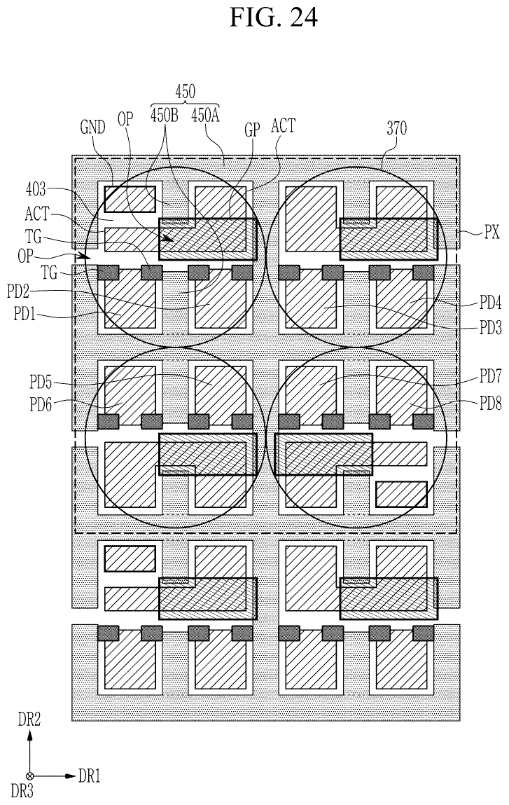

FIG. 24 shows a region like that of FIG. 23 with respect to another embodiment. Referring to FIG. 24, the image sensor according to the present embodiment is the same as the embodiment of FIG. 23 except that the open portion OP of the external pixel separation pattern 450A is formed only in a part thereof. A detailed description of the same elements will be omitted.

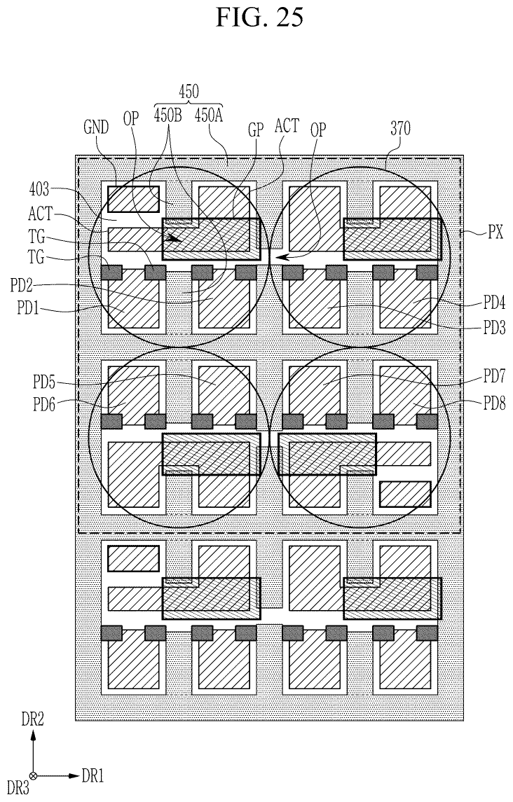

FIG. 25 shows a region like that of FIG. 23 with respect to another embodiment. Referring to FIG. 25, the image sensor according to the present embodiment is the same as the embodiment of FIG. 23 except that the open portion OP of the external pixel separation pattern 450A is formed only in a part thereof. A detailed description of the same elements will be omitted.

Although the open portion OP shapes of various pixel separation patterns are illustrated in FIGS. 9 to 25, these are only examples, and various combinations not illustrated in the drawings are also possible. That is, if the external pixel separation pattern 450A and the internal pixel separation pattern 450B include the open portion OP, and the width D1 of the external pixel separation pattern 450A is narrower than the width D2 of the internal pixel separation pattern 450B, the present disclosure may be included. Due to this open portion, the first substrates 400 of a plurality of photoelectric devices can be connected into one to share the ground pattern GND, and even if the size of one pixel decreases in a high-resolution image sensor, the degree of freedom of design in a plan view may be secured.

Additionally, the pixel separation patterns 450 are connected to each other in one direction in the image sensor according to the embodiment of FIGS. 4, 9 to 25, as previously described in FIG. 8. Therefore, even if a voltage is applied to the pixel separation pattern 450 outside the pixel array region AR, the voltage may be transmitted to the pixel separation pattern 450 inside the pixel array region AR.

Although the previous embodiment has been described as an example in which the shape of the pixel separation pattern 450 is the same in each pixel PX, the shape of the pixel separation pattern 450 may be different for each pixel in another embodiment.

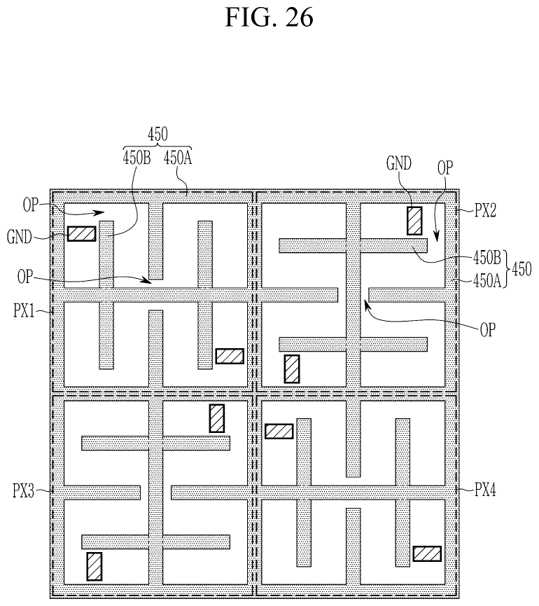

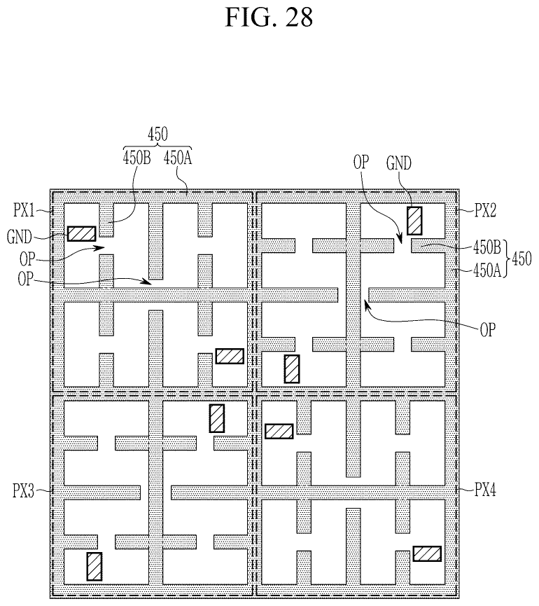

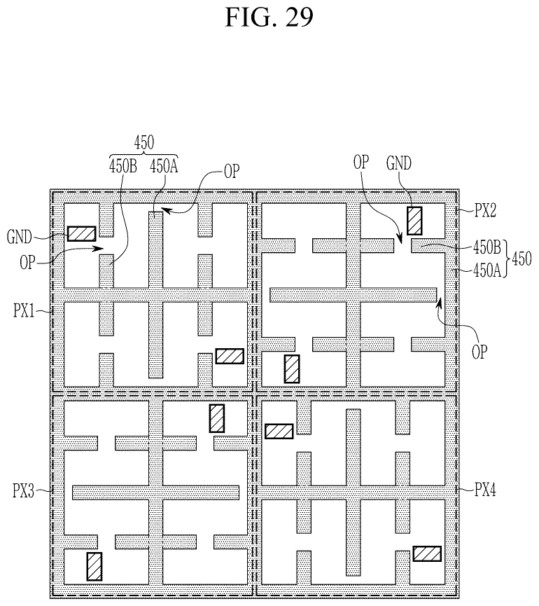

FIGS. 26 to 29 illustrate a pixel separation pattern 450 of a plurality of pixels according to various embodiments. For convenience of description, only the pixel separation pattern 450 and the ground pattern GND are illustrated in FIGS. 26 to 29. The arrangement of an active region ACT and the gate pattern may be the same as or different from those described in FIGS. 4, 9 to 25. That is, the arrangement of the active region, the floating diffusion region, and the gate pattern is not limited to a specific shape.

Referring to FIG. 26, the shape of the pixel separation pattern 450 may be the same in the first pixel PX1 and the fourth pixel PX4, and the arrangement of the pixel separation pattern 450 in the second pixel PX2 and the third pixel PX3 may be a shape obtained by rotating the first pixel PX1 and the fourth pixel PX4 by 90 degrees.

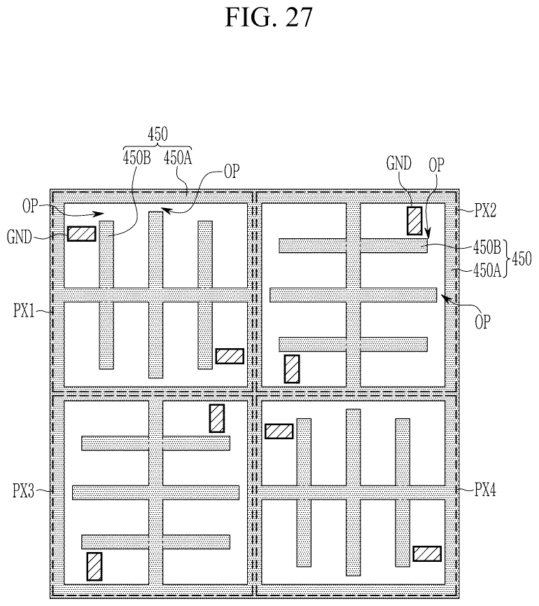

Likewise, in FIGS. 27 to 29, the shape of the pixel separation pattern 450 in the first pixel PX1 and the fourth pixel PX4 may be the same, and the arrangement of the pixel separation pattern 450 in the second pixel PX2 and the third pixel PX3 may be a shape obtained by rotating the first pixel PX1 and the fourth pixel PX4 by 90 degrees.

In addition, the previous embodiment illustrates a configuration in which the open portion of the external pixel separation pattern 450A is formed in a straight line, but in another embodiment, the open portion OP of the external pixel separation pattern 450A may be formed at a corner. In this case, the first substrates of the eight photovoltaic devices may be connected into one and may share one ground pattern GND.

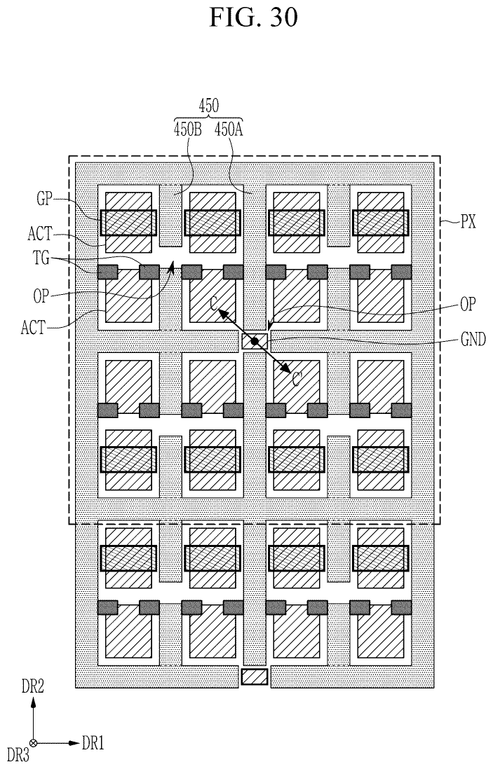

FIG. 30 illustrates an arrangement of pixels in a plan view of an image sensor according to another embodiment. Referring to FIG. 30, the open portion OP of the external pixel separation pattern 450A may be positioned at the center of the pixel. That is, as shown in FIG. 30, the open portion OP may be positioned at the intersection of the external pixel separation pattern 450A parallel to the first direction DR1 and the external pixel separation pattern 450A parallel to the second direction DR2. A ground pattern GND may be positioned in such open portion. In the case of having such a shape, a voltage may be applied to eight photoelectric conversion regions with one ground pattern GND. In addition, when vias VIA and wire for applying voltage to the ground pattern are positioned on top of the ground pattern GND, these vias can reduce interference between neighboring photovoltaic devices.

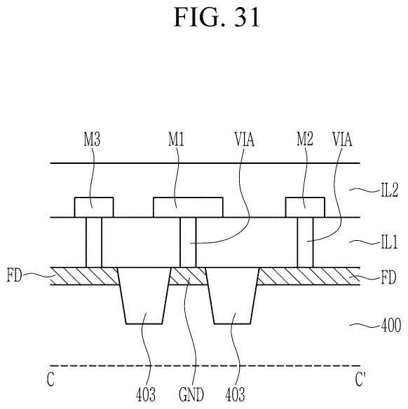

FIG. 31 is a cross-sectional view taken along line C-C′ of FIG. 30. For convenience of explanation, only some components are shown. Referring to FIG. 31, a via VIA for applying a ground voltage and a wire M1 connected to the via may be positioned on the ground pattern GND. Similarly, a via VIA and wires M2 and M3 for connecting the floating diffusion region FD and the floating diffusion region FD may be positioned in each photovoltaic device. At this time, a constant voltage may be supplied to the via VIA positioned on the ground pattern GND, thereby limiting and/or preventing operations of adjacent photovoltaic devices with the open portion OP interposed therebetween from affecting each other.

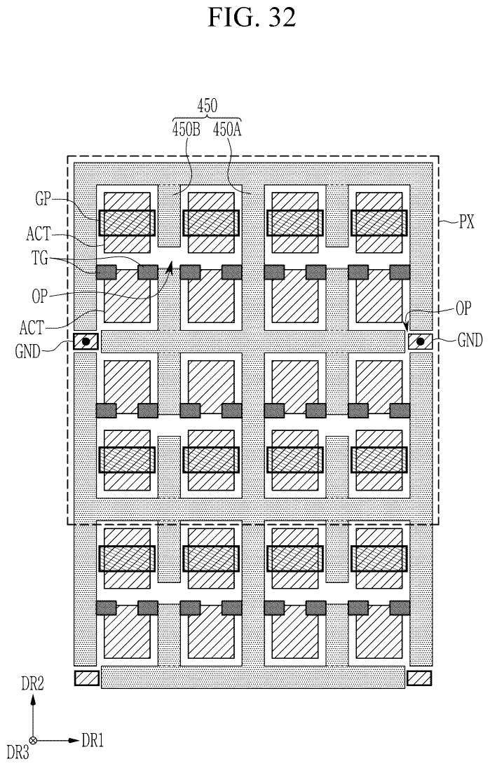

FIG. 32 illustrates a pixel separation pattern according to another embodiment. FIG. 32 is the same as an embodiment of FIG. 30 except for the position of the open portion OP of the external pixel separation pattern 450A and the position of the ground pattern GND. A detailed description of the same elements will be omitted.

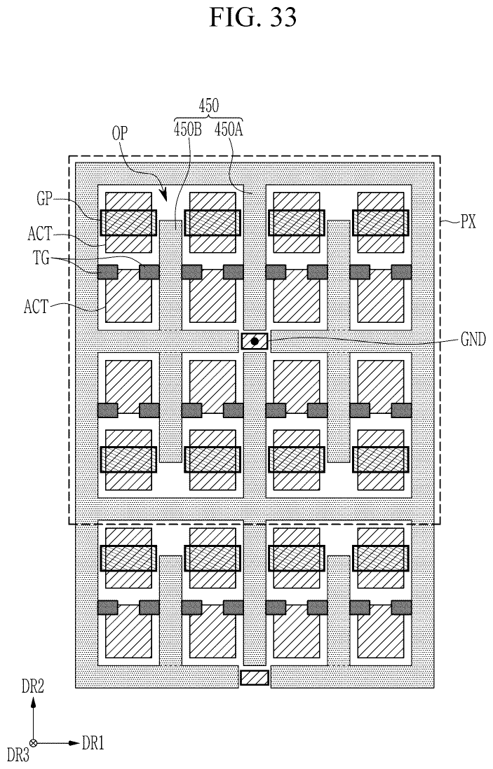

FIG. 33 illustrates the same region as FIG. 30 for another embodiment. Referring to FIG. 33, it is the same as FIG. 30 except for the position of the open portion OP of the internal pixel separation pattern 450B. A detailed description of the same elements will be omitted.

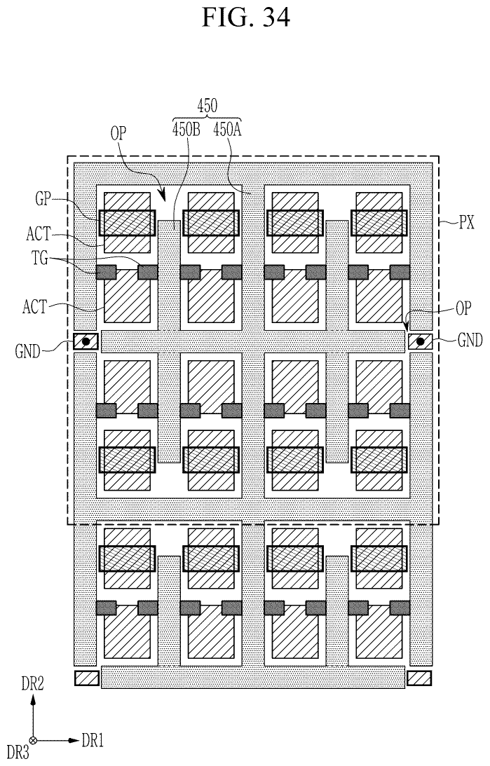

FIG. 34 shows the same region as FIG. 33 for another embodiment. Referring to FIG. 34, it is the same as FIG. 33 except for the position of the open portion OP of the internal pixel separation pattern 450B. A detailed description of the same elements will be omitted.

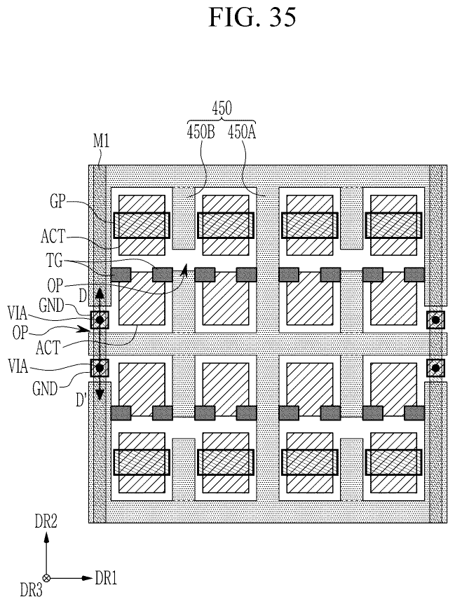

FIG. 35 illustrates pixel arrangement of an image sensor according to another embodiment. Referring to FIG. 35, in the present embodiment, the ground pattern may be formed in the open portion OP of the external pixel separation pattern 450A.

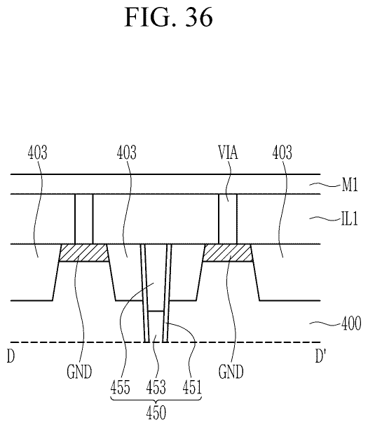

It is a cross-sectional view taken along line D-D′ of FIG. 36 and FIG. 35. Referring to FIG. 36, the two ground patterns GND may be connected by the same wire M1. As shown in FIGS. 35 and 36, the ground pattern GND may be connected to the wire M1, and the wire M1 may be positioned to overlap the external pixel separation pattern 450A. A constant voltage may be supplied to the wire M1, thereby limiting and/or preventing operations of adjacent photovoltaic devices from affecting each other.

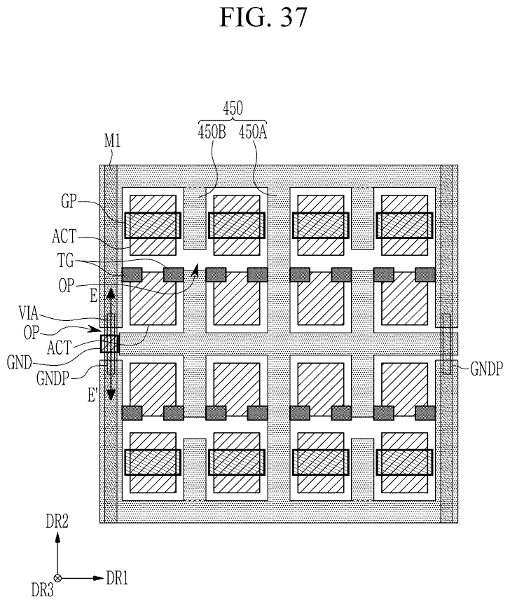

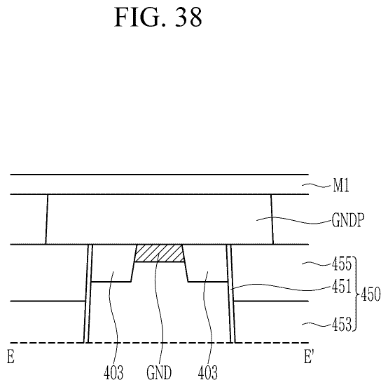

FIG. 37 illustrates pixel arrangement of an image sensor according to another embodiment. FIG. 38 is a cross-sectional view taken along line E-E′ of FIG. 37. Referring to FIGS. 37 and 38, the image sensor according to the present embodiment is the same as that of the embodiment of FIG. 32, except that a pad part GNDP is positioned between the ground pattern GND and the wire M1. A detailed description of the same elements will be omitted. In the embodiments of FIGS. 37 and 38, a constant voltage may be supplied to the pad part GNDP and the wire M1, thereby limiting and/or preventing operations of adjacent photovoltaic devices from affecting each other.

As described above, image sensors according to some example embodiments may include an open portion in a pixel separation pattern. Therefore, the number of components such as ground pads can be reduced in one pixel, and even if the size of the pixel decreases in a high-resolution image sensor, the degree of freedom of design in a plan view may be increased. Additionally, in configurations according to some example embodiments, the pixel separation pattern outside the pixel array region and the pixel array region may be connected in one direction, thus reducing dark current by applying a negative voltage to the pixel separation pattern outside the pixel array region.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While some examples have been described in connection with what is presently considered to be some practical embodiments, it is to be understood that the disclosure is not limited to the disclosed embodiments, and that the disclosure is intended to cover various modifications and equivalent arrangements included within the spirit and scope of the appended claims.

### DESCRIPTION OF SYMBOLS

GND: Ground pattern 450: Pixel separation pattern
450A: External pixel separation pattern
450B: Internal pixel separation pattern
OP: Open portion
451: First separation pattern
453: Second separation pattern
455: Capping pattern
GP: Gate pattern
ACT: Active pattern
403: Device separation pattern

What is claimed is:

1. An image sensor comprising:
a substrate;
a plurality of photovoltaic devices in the substrate;
a plurality of microlenses on the plurality of photovoltaic devices; and
a pixel separation pattern between the plurality of photovoltaic devices, the pixel separation pattern separating the substrate, wherein
the plurality of photovoltaic devices are arranged in groups of photovoltaic devices,
photovoltaic devices in each group of photovoltaic devices, among the groups of photovoltaic devices, correspond to a same microlens among the plurality of microlenses,
the groups of photovoltaic devices correspond to different microlenses among the plurality of microlenses,
the pixel separation pattern comprises an internal pixel separation pattern and an external pixel separation pattern,
the internal pixel separation pattern is between photovoltaic devices of a same group among the groups of photovoltaic devices,
the external pixel separation pattern is between the groups of photovoltaic devices, and
a width of an open portion of the internal pixel separation pattern is greater than a width of an open portion of the external pixel separation pattern.

2. The image sensor of claim 1, wherein
the substrate comprises a pixel array region and a pad region, and
the pixel separation pattern is connected in one direction in the pad region and the pixel array region.

3. The image sensor of claim 1, further comprising:
a plurality of active patterns and a plurality of ground patterns on the substrate.

4. The image sensor of claim 3, wherein
the plurality of active patterns are in the open portion of the internal pixel separation pattern.

5. The image sensor of claim 3, wherein
each of the plurality of photovoltaic devices are electrically connected to a corresponding ground pattern among the plurality of ground patterns.

6. The image sensor of claim 3, wherein
at least four of the plurality of photovoltaic devices are side by side along a first direction and electrically connected to one ground pattern among the plurality of ground patterns.

7. The image sensor of claim 1, wherein
the open portion of the internal pixel separation pattern and the open portion of the external pixel separation pattern are side by side along a first direction.

8. The image sensor of claim 1, wherein
the open portion of the internal pixel separation pattern and the open portion of the external pixel separation pattern are not side by side in a first direction.

9. The image sensor of claim 1, further comprising:
a plurality of ground patterns on the substrate, wherein
one pixel of the image sensor comprises eight photovoltaic devices among the plurality of photovoltaic devices, four microlenses among the plurality of microlenses, and two ground patterns among the plurality of ground patterns.

10. An image sensor comprising:
a substrate;
a plurality of photovoltaic devices in the substrate;
a plurality of microlenses on the plurality of photovoltaic devices;
a ground pattern; and
a pixel separation pattern between the plurality of photovoltaic devices, the pixel separation pattern separating the substrate, wherein
the plurality of photovoltaic devices are arranged in groups of photovoltaic devices,
photovoltaic devices in each group of photovoltaic devices, among the groups of photovoltaic devices, correspond to a same microlens among the plurality of microlenses,
the groups of photovoltaic devices correspond to different microlenses among the plurality of microlenses,
the pixel separation pattern comprises an internal pixel separation pattern and an external pixel separation pattern,
the internal pixel separation pattern is between photovoltaic devices of a same group among the groups of photovoltaic devices,
the external pixel separation pattern is between the groups of photovoltaic devices,
the internal pixel separation pattern and the external pixel separation pattern each include an open portion, and
the ground pattern is in the open portion of the external pixel separation pattern.

11. The image sensor of claim 10, wherein
a width of the open portion of the internal pixel separation pattern is greater than a width of the open portion of the external pixel separation pattern.

12. The image sensor of claim 10, wherein
the open portion of the external pixel separation pattern is at an intersection where a first portion of the external pixel separation pattern intersects a second portion of the external pixel separation pattern,
the first portion of the external pixel separation pattern is aligned side by side in a first direction,
the second portion of the external pixel separation pattern is aligned side by side in a second direction, and
the second direction is perpendicular to the first direction.

13. The image sensor of claim 12, wherein
the ground pattern is among a plurality of ground patterns,
one pixel of the image sensor comprises eight photovoltaic devices among the plurality of photovoltaic devices, four microlenses among the plurality of microlenses, and one ground pattern among the plurality of ground patterns, and
regions of the substrate corresponding to the eight photovoltaic devices are connected to each other to provide one portion of the substrate.

14. The image sensor of claim 10, further comprising:
a wire on the ground pattern, wherein
the wire is electrically connected to the ground pattern, and
the wire overlaps the external pixel separation pattern.

15. The image sensor of claim 10, further comprising:
wire patterns on the substrate, wherein
the open portion of the external pixel separation pattern is among open portions in external pixel separation patterns,
the ground pattern is among ground patterns in the open portions of adjacent external pixel separation patterns among the external pixel separation patterns, respectively, and
adjacent ground patterns, among the ground patterns, are electrically connected to a same wire among the wire patterns.

16. An image sensor comprising:
a substrate;
a plurality of photovoltaic devices in the substrate;
a plurality of microlenses on the plurality of photovoltaic devices;
a pixel separation pattern between the plurality of photovoltaic devices, the pixel separation pattern separating the substrate, wherein
the plurality of photovoltaic devices are arranged in groups of photovoltaic devices,
photovoltaic devices in each group of photovoltaic devices, among the groups of photovoltaic devices, correspond to a same microlens among the plurality of microlenses,
the groups of photovoltaic devices correspond to different microlenses among the plurality of microlenses,
the pixel separation pattern comprises an internal pixel separation pattern and an external pixel separation pattern,
the internal pixel separation pattern is between photovoltaic devices of a same group among the groups of photovoltaic devices,
the external pixel separation pattern is between the groups of photovoltaic devices,
each of the internal pixel separation pattern and the external pixel separation pattern comprises an open portion, and
the external pixel separation pattern and the internal pixel separation pattern are connected to each other.

17. The image sensor of claim 16, wherein
the substrate comprises a pad region and a pixel array region, and
the pixel separation pattern is connected in one direction in the pad region and the pixel array region.

18. The image sensor of claim 17, wherein
the image sensor is configured to have a voltage is applied to the pixel separation pattern in the pad region.

19. The image sensor of claim 16, further comprising:
a plurality of active patterns and a plurality of ground patterns on the substrate, wherein
each of the plurality of photovoltaic devices are electrically connected to a corresponding ground pattern among the plurality of ground patterns.

20. The image sensor of claim 16, further comprising:
a ground pattern in the open portion of the external pixel separation pattern.
